(19) United States
(12) Patent Application Publication
(10) Pub. No.: US 2025/0015182 A1
(43) Pub. Date: Jan. 9, 2025

(54) SEMICONDUCTOR DEVICE AND MANUFACTURING METHOD OF THE SAME, AND ELECTRONIC SYSTEM

(71) Applicant: SAMSUNG ELECTRONICS CO., LTD., SUWON-SI (KR)

(72) Inventors: Siyeong Yang, SUWON-SI (KR); Yuyeon Kim, SUWON-SI (KR); Jaeho Jung, SUWON-SI (KR)

(21) Appl. No.: 18/444,592

(22) Filed: Feb. 16, 2024

(30) Foreign Application Priority Data
Jul. 3, 2023 (KR) 10-2023-0085942

(51) Int. Cl. H01L 29/78; H01L 25/065; H01L 29/66; H10B 41/27; H10B 43/27; H10B 80/00

(52) U.S. Cl. CPC H01L 29/7827; H01L 29/66666; H10B 41/27; H10B 43/27; H10B 80/00; H01L 25/0657; H01L 2225/06506; H01L 2225/0651; H01L 2225/06562

(57) ABSTRACT

A semiconductor device includes a gate stacking structure that includes a plurality of gate electrodes and a plurality of insulating layers alternately stacked with each other, and a plurality of channel structures that penetrate the gate stacking structure. The plurality of channel structures include a first channel structure that includes a first channel layer, and a plurality of second channel structures adjacent to the first channel structure and that include a plurality of second channel layers. The first channel layer in the first channel structure and the plurality of second channel layers in the plurality of second channel structures have a same crystal orientation.

### CROSS-REFERENCE TO RELATED APPLICATION

This application claims priority under 35 U.S.C. § 119 from Korean Patent Application No. 10-2023-0085942, filed in the Korean Intellectual Property Office on Jul. 3, 2023, the contents of which are herein incorporated by reference in their entirety.

### TECHNICAL FIELD

Embodiments of the present disclosure are directed to a semiconductor device and a manufacturing method of the same, and an electronic system.

### DISCUSSION OF THE RELATED ART

In electronic systems that implement data storage, a semiconductor device that can store high-capacity of data is in demand. Accordingly, a method for increasing data storage capacity of a semiconductor device is being researched. As one method for increasing the data storage capacity of a semiconductor device, a semiconductor device that includes three-dimensionally arranged memory cells instead of two-dimensionally arranged memory cells has been proposed.

### SUMMARY

Embodiments of the present disclosure provide a semiconductor device, a manufacturing method of the same, and an electronic system that can increase performance and productivity.

A semiconductor device according to an embodiment includes a gate stacking structure that includes a plurality of gate electrodes and a plurality of insulating layers alternately stacked with each other, and a plurality of channel structures that penetrate the gate stacking structure. The plurality of channel structures include a first channel structure that includes a first channel layer, and a plurality of second channel structures adjacent to the first channel structure and that include a plurality of second channel layers. The first channel layer in the first channel structure and the plurality of second channel layers in the plurality of second channel structures have a same crystal orientation.

An electronic system according to an embodiment includes a main substrate, a semiconductor device disposed on the main substrate, and a controller electrically connected to the semiconductor device.

A manufacturing method of a semiconductor device according to an embodiment includes forming a stacking structure, forming a plurality of preliminary channel structures, forming a plurality of channel layers, and forming a plurality of gate electrodes. The stacking structure includes a plurality of sacrificial insulating layers and a plurality of insulating layers alternately stacked with each other. The plurality of preliminary channel structures penetrate the stacking structure and include a plurality of preliminary channel layers. Each of the plurality of preliminary channel layers has an amorphous structure. The plurality of channel layers have a single crystal structure or a quasi-single crystal structure that have a same crystal orientation and are formed by performing a heat treatment process that crystallizes the plurality of preliminary channel layers of the plurality of preliminary channel structures. Forming the plurality of gate electrodes includes replacing the plurality of sacrificial insulating layers with the plurality of gate electrodes.

According to an embodiment, a channel layer has a single crystal structure or a quasi-single crystal structure that increases cell current. For example, a plurality of channel layers of a plurality of channel structures have the same crystal orientation. Accordingly, the plurality of channel structures have excellent and uniform cell properties, and defects of a semiconductor device can be reduced by the stably crystallized channel layer. As a result, performance and productivity of the semiconductor device can be increased.

As such, a semiconductor device that achieves excellent performance by including a plurality of channel layers of a plurality of channel structures that have the same crystal orientation can be manufactured in a simple process. Accordingly, the productivity of the semiconductor device can be increased.

### BRIEF DESCRIPTION OF THE DRAWINGS

FIG. 1 is a schematic cross-sectional view of a semiconductor device according to an embodiment.

FIG. 2 is an enlarged cross-sectional view of a channel structure of a semiconductor device shown in FIG. 1.

FIG. 3 is an enlarged top plan view of a cell array region of a semiconductor device shown in FIG. 1.

FIG. 4 is an enlarged cross-sectional view of a plurality of channel structures of a semiconductor device shown in FIG. 1.

FIG. 5 illustrates crystal planes of a channel layer in the semiconductor device shown in FIG. 1.

FIGS. 6A to 6F are partial cross-sectional views that illustrate a manufacturing method of a semiconductor device according to an embodiment.

FIGS. 7A to 7D are cross-sectional views that illustrate a manufacturing process of a metal-containing substrate used in a manufacturing method of a semiconductor device according to an embodiment.

FIG. 8 is a schematic cross-sectional view of a semiconductor device according to an embodiment.

FIG. 9 is a schematic cross-sectional view of a semiconductor device according to a modified embodiment.

FIG. 10 illustrates an electronic system that includes a semiconductor device according to an embodiment.

FIG. 11 is a schematic perspective view of an electronic system that includes a semiconductor device according to an embodiment.

FIG. 12 is a schematic cross-sectional view of a semiconductor package according to an embodiment.

FIG. 13 is a schematic cross-sectional view of a semiconductor package according to an embodiment.

### DETAILED DESCRIPTION

Embodiments of the present disclosure will be described more fully hereinafter with reference to the accompanying drawings for those skilled in the art to which the present disclosure pertains to easily practice the present disclosure. Embodiments of the present disclosure may be implemented in various different forms and are not limited to embodiments described herein.

It will be understood that when a component such as a layer, film, region, or substrate is referred to as being “on” another component, it may be directly on other component or intervening components may also be present. In contrast, when a component is referred to as being “directly on” another component, there are no intervening components present. Further, when a component is referred to as being “on” or “above” a reference component, a component may be positioned on or below the reference component, and does not necessarily be “on” or “above” the reference component toward an opposite direction of gravity.

Further, throughout the specification, a phrase “in a plan view” may indicate a case where a portion is viewed from above or a top portion, and a phrase “in a cross-sectional view” may indicate when a cross-section taken along a vertical direction is viewed from a side.

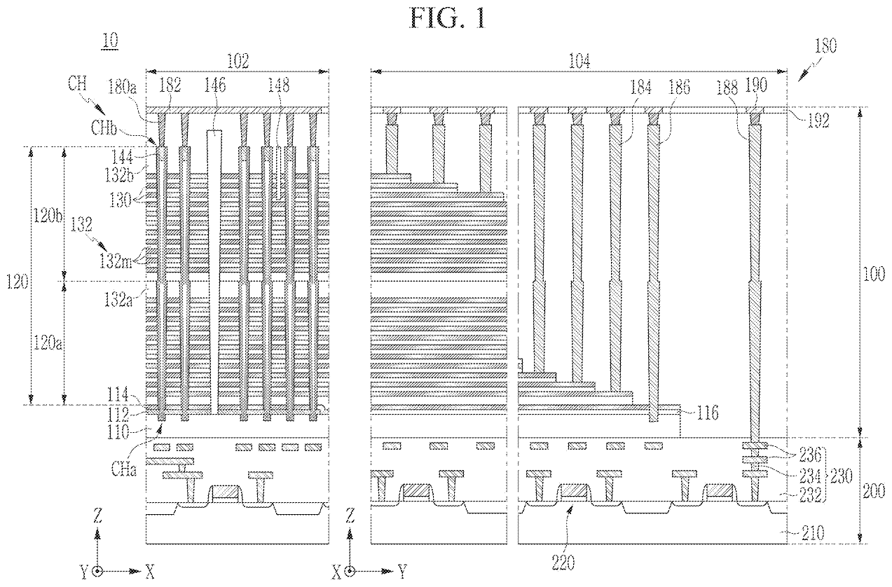

Hereinafter, a semiconductor device and a manufacturing method of the same according to an embodiment will be described in detail with reference to FIGS. 1 to 5, 6A to 6F, and 7A to 7D.

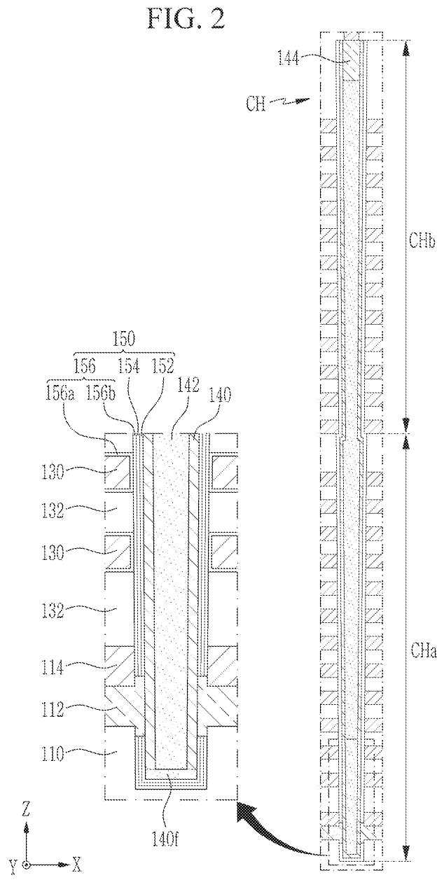

FIG. 1 is a schematic cross-sectional view of a semiconductor device according to an embodiment, and FIG. 2 is an enlarged cross-sectional view of an example of a channel structure included in the semiconductor device shown in FIG. 1.

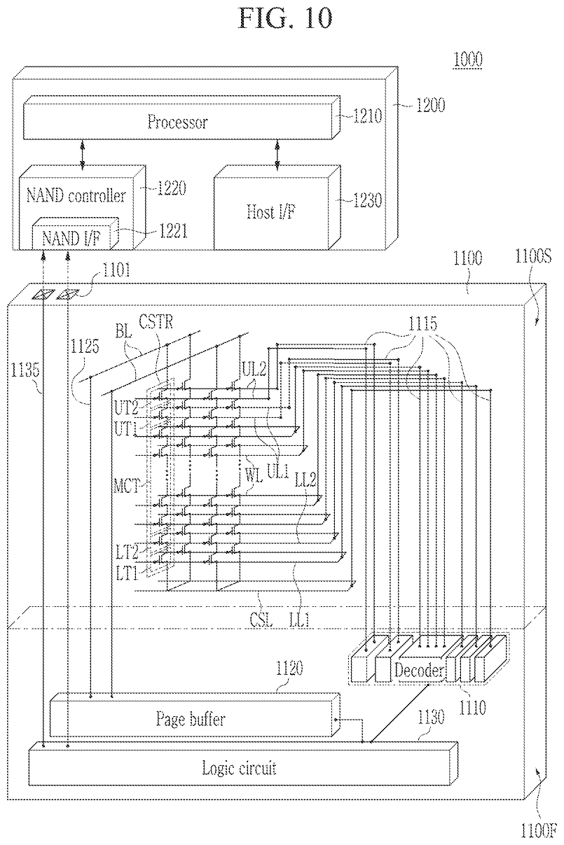

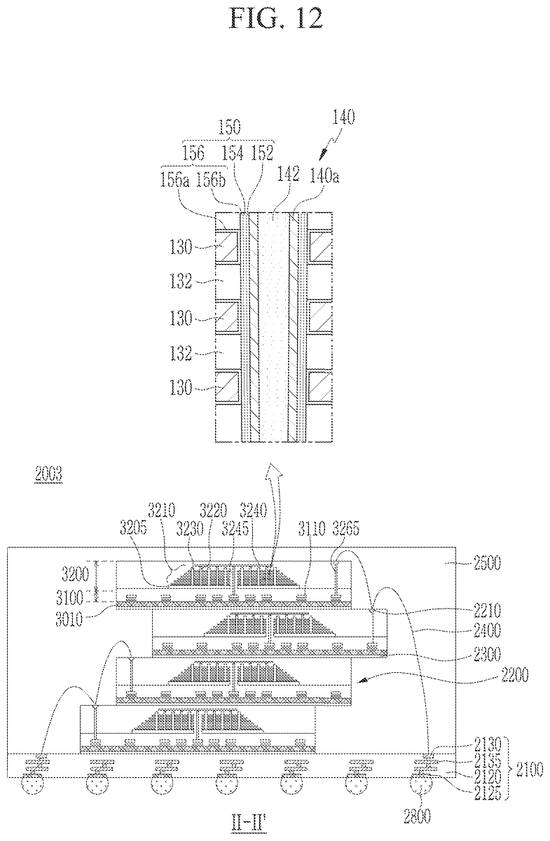

Referring to FIGS. 1 and 2, a semiconductor device 10 according to an embodiment includes a cell region 100 that includes a memory cell structure, and a circuit region 200 that includes a peripheral circuit structure that controls an operation of the memory cell structure. For example, the circuit region 200 and the cell region 100 are portions that respectively correspond to a first structure 1100F and a second structure 1100S of a semiconductor device 1100 included in an electronic system 1000 shown in FIG. 10. The circuit region 200 and the cell region 100 include a first structure 3100 and a second structure 3200 of a semiconductor chip 2200 shown in FIG. 12, respectively.

The circuit region 200 includes a peripheral circuit structure formed on a first substrate 210, and the cell region 100 includes a gate stacking structure 120 and a channel structure CH formed on a second substrate 110 as memory cell structures. A first wiring portion 230 is disposed in the circuit region 200, and a second wiring portion 180 electrically connected to the memory cell structure is disposed in the cell region 100.

In an embodiment, the cell region 100 is positioned on the circuit region 200. Accordingly, an area that corresponds to the circuit region 200 is not needed separately from the cell region 100, thereby reducing an area of the semiconductor device 10. However, embodiments are not necessarily limited thereto, and in some embodiments, the circuit region 200 is adjacent to the cell region 100. Other variations are possible in other embodiments.

The circuit region 200 includes the first substrate 210, a circuit element 220 and the first wiring portion 230 formed on the first substrate 210.

The first substrate 210 is a semiconductor substrate that includes a semiconductor material. For example, the first substrate 210 may include or be made of a semiconductor material, or may be a semiconductor layer formed on a base substrate. For example, the first substrate 210 includes or is made of a single crystal silicon, polysilicon, epitaxial silicon, germanium, silicon-germanium, silicon-on-insulator (SOI), or germanium-on-insulator (GOI), etc.

The circuit element 220 on the first substrate 210 includes various circuit elements that control the operation of the memory cell structure in the cell region 100. For example, the circuit element 220 includes peripheral circuit structures such as a decoder circuit (reference numeral 1110 in FIG. 10), a page buffer (reference numeral 1120 in FIG. 10), a logic circuit (reference numeral 1130 in FIG. 10), etc.

The circuit element 220 includes, for example, a transistor, but embodiments are not necessarily limited thereto. For example, the circuit element 220 includes active elements such as transistors, and/or passive elements such as capacitors, resistors, inductors, etc.

The first wiring portion 230 on the first substrate 210 is electrically connected to the circuit element 220. In an embodiment, the first wiring portion 230 includes a plurality of wiring layers 236 spaced apart with a first insulating layer 232 interposed therebetween and connected to form a desired path by a contact via 234. The wiring layer 236 and/or the contact via 234 include any of various conductive materials, and the first insulating layer 232 includes any of various insulating materials.

The cell region 100 includes a cell array region 102 and a connection region 104. The gate stacking structure 120 and the channel structure CH are formed on the second substrate 110 in the cell array region 102. A structure that connects the gate stacking structure 120 and/or the channel structure CH to the circuit region 200 or an external circuit is positioned in the cell array region 102 and/or the connection region 104. In an embodiment, the second substrate 110 includes a semiconductor layer that includes a semiconductor material. For example, the second substrate 110 is a semiconductor substrate that includes or is made of a semiconductor material, or is a semiconductor layer formed on a base substrate. For example, the second substrate 110 is made of at least one of silicon, germanium, silicon-germanium, silicon-on-insulator, or germanium-on-insulator, etc. A P-type or N-type impurity may be doped into the semiconductor layer of the second substrate 110. For example, an N-type impurity, such as phosphorus (P) or arsenic (As), is doped. However, embodiments are not necessarily limited to the materials of the second substrate 110, the conductivity type of impurities doped to the semiconductor layer, and the material.

In the cell array region 102, the gate stack structure 120 includes a cell insulating layer 132 and a gate electrode 130 alternately stacked on a first surface, such as a front surface or an upper surface of the second substrate 110, and the channel structure CH extends in a direction that crosses the second substrate 110 by penetrating the gate stack structure 120.

In an embodiment, horizontal conductive layers 112 and 114 are provided in the cell array region 102 between the second substrate 110 and the gate stacking structure 120. The horizontal conductive layers 112 and 114 electrically connect the channel structure CH and the second substrate 110. For example, the horizontal conductive layers 112 and 114 include a first horizontal conductive layer 112 disposed on the first surface of the second substrate 110, and further include a second horizontal conductive layer 114 disposed on the first horizontal conductive layer 112. In some regions of the connection region 104, the first horizontal conductive layer 112 is not provided between the second substrate 110 and the gate stack structure 120, and a horizontal insulating layer 116 is provided. A part of the horizontal insulating layer 116 in the cell array region 102 is replaced with the first horizontal conductive layer 112 in a manufacturing process, and another part of the horizontal insulating layer 116 remains in the connection region 104.

The first horizontal conductive layer 112 is a part of a common source line of the semiconductor device 10. For example, the first horizontal conductive layer 112 and the second substrate 110 function as a common source line. As shown in an enlarged view of FIG. 2, the channel structure CH penetrates the horizontal conductive layers 112 and 114 and extends to reach the second substrate 110, and a gate dielectric layer 150 is removed at the portion where the first horizontal conductive layer 112 is positioned so that the first horizontal conductive layer 112 is directly connected to a channel layer 140 at a perimeter of the channel layer 140.

The first and second horizontal conductive layers 112 and 114 include a semiconductor material, such as polysilicon. For example, the first horizontal conductive layer 112 is a polysilicon layer doped with an impurity, and the second horizontal conductive layer 114 is a polysilicon layer doped with an impurity or is a layer containing an impurity that diffused from the first horizontal conductive layer 112. However, embodiments are not necessarily limited thereto, and in some embodiments, the second horizontal conductive layer 114 includes or is made of an insulating material. In some embodiments, the second horizontal conductive layer 114 is not separately provided.

The gate stacking structure 120 is positioned on the second substrate 110, such as on the first and second horizontal conductive layers 112 and 114 on the second substrate 110.

The cell insulating layer 132 includes an interlayer insulating layer 132m interposed between two neighboring gate electrodes 130 in each of a plurality of gate stacking structures 120a and 120b, and upper insulating layers 132a and 132b disposed at upper portions of each of the plurality of gate stacking structures 120a and 120b, respectively. In an embodiment, thicknesses of the plurality of cell insulating layers 132 are not the same. For example, thicknesses of the upper insulating layers 132a and 132b are greater than a thickness of the interlayer insulating layer 132m. For simplicity, the cell insulating layer 132 is illustrated in the connection region 104 in the drawing as an integral unit without a boundary. However, one or more of insulating layers in the connection region 104 may have a stacking structure. A shape and a structure of the cell insulating layer 132 may be variously modified according to embodiments.

The gate electrode 130 includes one or more conductive materials. For example, the gate electrode 130 includes one or more of a metal, such as tungsten (W), copper (Cu), or aluminum (Al), etc., polysilicon, a metal nitride, such as titanium nitride (TiN) or tantalum nitride (TaN), etc., or a combination thereof. As shown in the enlarged view of FIG. 2, a part of a blocking layer 156 that includes or is made of an insulating material, such as a first blocking layer 156a, is located outside the gate electrode 130. The cell insulating layer 132 includes one or more insulating materials. For example, the cell insulating layer 132 includes one or more of silicon oxide, silicon nitride, silicon oxynitride, a low dielectric constant material that has a lower dielectric constant than silicon oxide, or a combination thereof.

In an embodiment, the channel structure CH penetrates the gate stacking structure 120 and extends in a direction that crosses the second substrate 110, such as, a vertical direction (Z-axis direction in the drawing) that is normal to the second substrate 110.

The channel structure CH includes a channel layer 140, and a gate dielectric layer 150 positioned on the channel layer 140 between the gate electrode 130 and the channel layer 140. The channel structure CH further includes a core insulating layer 142 positioned inside the channel layer 140, but in another embodiment, no core insulating layer 142 is provided. The channel structure CH further includes a channel pad 144 on the channel layer 140 and/or the gate dielectric layer 150. The gate dielectric layer 150 includes a tunneling layer 152, a charge storage layer 154, and a blocking layer 156 sequentially formed on the channel layer 140.

Each channel structure CH forms one memory cell string, and a plurality of channel structures CH are spaced apart from each other and form rows and columns in a plan view. For example, the plurality of channel structures CH are arranged in any of various patterns, such as a lattice pattern or a zigzag pattern, in a plan view. The channel structure CH has a pillar shape. For example, the channel structure CH has an inclined side surface so that the width narrows as it approaches the second substrate 110 due to a high aspect ratio, when viewed in a cross-sectional view. However, embodiments are not necessarily limited thereto, and in other embodiments, an arrangement, structure, and/or shape of the channel structure CH is variously modified.

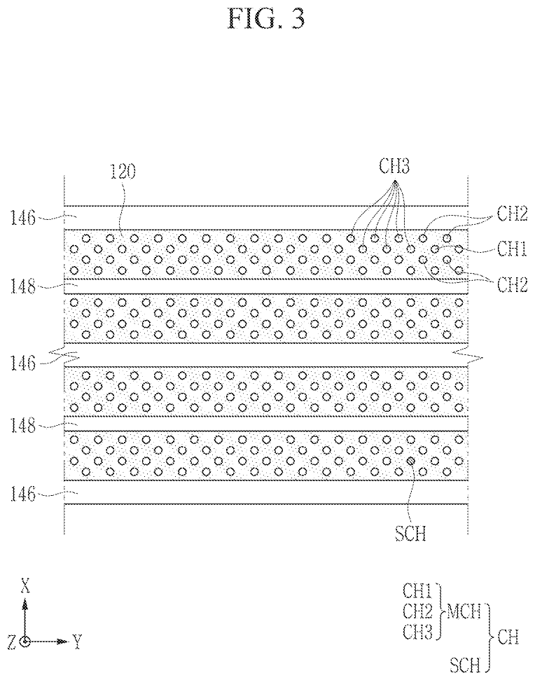

The channel layer 140 includes a semiconductor material, such as silicon. In an embodiment, the channel layer 140 has a single crystal structure or quasi-single crystal structure. This will be described in more detail with reference to FIGS. 3 to 5, below. The core insulating layer 142 includes at least one insulating material. For example, the core insulating layer 142 includes at least one of silicon oxide, silicon nitride, silicon oxynitride, or a combination thereof.

The tunneling layer 152 includes an insulating material that can tunnel charges, such as silicon oxide or silicon oxynitride, etc. The charge storage layer 154 is used as a data storage region, and the charge storage layer 154 includes at least one of polysilicon or silicon nitride, etc. The blocking layer 156 includes an insulating material that can suppress or prevent undesirable flow of charges into the gate electrode 130. For example, the blocking layer 156 includes at least one of silicon oxide, silicon nitride, silicon oxynitride, a high dielectric constant material that has a higher dielectric constant than silicon oxide, or a combination thereof. In an embodiment, the blocking layer 156 includes a first blocking layer 156a, which includes a portion that horizontally extends along the gate electrode 130, and a second blocking layer 156b that vertically extends between the first blocking layer 156a and the charge storage layer 154.

However, materials and stacking structures of the channel layer 140, the core insulating layer 142, and the gate dielectric layer 150 may be modified in various ways, and embodiments are not necessarily limited thereto.

The channel pad 144 covers an upper surface of the core insulating layer 142 and is electrically connected to the channel layer 140. The channel pad 144 includes a conductive material, such as polysilicon doped with impurities, but is not necessarily limited thereto.

In an embodiment, the gate stacking structure 120 includes the plurality of gate stacking structures 120a and 120b sequentially stacked on the second substrate 110. A number of stacked gate electrodes 130 can be increased, which increases the number of memory cells with a stable structure. FIG. 2 illustrates that the gate stacking structure 120 includes first and second gate stacking structures 120a and 120b. However, embodiments are not necessarily limited thereto, and in other embodiments, the gate stacking structure 120 includes one, or three or more gate stacking structures.

As described above, when the plurality of gate stacking structures 120a and 120b are provided, the channel structure CH include a plurality of channel portions CHa and CHb that respectively penetrate the plurality of gate stacking structures 120a and 120b. The plurality of channel portions CHa and CHb are connected to each other. Each of the plurality of channel portions CHa and CHb has an inclined side surface whose width becomes narrower with decreasing distance from the second substrate 110 due to a high aspect ratio when viewed in a cross-sectional view. Due to a width difference, a bent portion is provided where each of the plurality of channel portions CHa and CHb is connected. In some embodiments, the plurality of channel portions CHa and CHb have an inclined side surface that is continuously connected, without a bent portion. FIG. 2 illustrates that the gate dielectric layer 150, the channel layer 140, and the core insulating layer 142 of the plurality of channel portions CHa and CHb have an integral structure. However, embodiments are not necessarily limited thereto, and in other embodiments, the gate dielectric layer 150, the channel layer 140, and the core insulating layer 142 of the plurality of channel portions CHa and CHb are separately formed but electrically connected to each other. In addition, in some embodiments, a separate channel pad is additionally provided at the connection portion of the plurality of channel portions CHa and CHb. As such, embodiments are not necessarily limited to a particular shape or structure of the plurality of channel portions Cha and CHb.

In an embodiment, the gate stacking structure 120 extends in a direction, such as a vertical direction or Z-axis direction in the drawing, that crosses the second substrate 110 is partitioned into a plurality of portions in a plan view by a separation structure 146 that penetrates the gate stacking structure 120. An upper separation region 148 is disposed at an upper portion of the gate stacking structure 120. In a plan view, the separation structure 146 and/or the upper separation region 148 are provided in plural, extend in a first direction (Y-axis direction in the drawing) and are spaced apart from each other by a predetermined distance in a second direction (X-axis direction in the drawing) that crosses the first direction.

Due to the separation structure 146, in a plan view, the plurality of gate stacking structures 120 each extend in the first direction (Y-axis direction in the drawing) and are spaced apart from each other by a predetermined distance in the second direction (X-axis direction in the drawing). Each gate stacking structure 120 partitioned by the separation structure 146 configures one memory cell block. However, embodiments are not necessarily limited thereto, and a region or an area of the memory cell block is not necessarily limited thereto.

For example, the separation structure 146 penetrates the gate stacking structure 120 and extends into the second substrate 110, and the upper separation region 148 separates one or some of the plurality of gate electrodes 130. The upper separation region 148 is disposed between the separation structures 146.

For example, FIG. 1 illustrates that the separation structure 146 has an inclined side surface whose width gradually decreases toward the second substrate 110 due to a high aspect ratio when viewed in a cross-sectional view, but embodiments are not necessarily limited thereto. In some embodiments, a side of the separation structure 146 is vertical to the second substrate 110, or has a bent portion where the plurality of stacking structures 120a and 120b are connected.

The separation structure 146 and/or the upper separation region 148 are formed from insulating materials. For example, the separation structure 146 and/or the upper separation region 148 include an insulating material such as at least one of silicon oxide, silicon nitride, or silicon oxynitride, etc. However, embodiments are not necessarily limited thereto, and in some embodiments, a structure, a shape, and a material of the separation structure 146 or the upper separation region 148 are variously modified.

A connection region 104 and a second wiring portion 180 are provided that connect the gate stacking structure 120 and the channel structure CH to the circuit region 200 or an external circuit. The connection region 104 is located at a periphery of the cell array region 102, and at least a part of the second wiring portion 180 is positioned in the connection region 104.

The second wiring portion 180 includes various members, units, wirings, etc., that electrically connect the gate electrode 130, the channel structure CH, the horizontal conductive layers 112 and 114, and/or the second substrate 110 to the circuit region 200 or the external circuit. For example, the second wiring portion 180 includes a bit line 182, a gate contact portion 184, a source contact portion 186, a through plug 188, and contact vias 180a respectively connected thereto, and a connection wire 190 that connects them.

The bit line 182 is disposed in the cell array region 102 on the cell insulating layer 132 of the gate stacking structure 120. The bit line 182 extends in a direction (X-axis direction in the drawing) that crosses a direction in which the gate electrode 130 extends. The bit line 182 is electrically connected to the channel structure CH, such as the channel pad 144, through the contact via 180a.

The plurality of gate electrodes 130 extend through the cell insulating layer 132 in the first direction (Y-axis direction in the drawing) in the connection region 104, and extension lengths of the plurality of gate electrodes 130 in the connection region 104 sequentially decrease as distances between the gate electrode 130 and the second substrate 110 increases. For example, the plurality of gate electrodes 130 have a stepped shape in the connection region 104. For example, the plurality of gate electrodes 130 have a stepped shape in one direction or in a plurality of directions. In the connection region 104, the plurality of gate contact portions 184 are respectively electrically connected to the plurality of gate electrodes 130. In the connection region 104, the source contact portion 186 is electrically connected to the horizontal conductive layers 112 and 114 and/or the second substrate 110 by penetrating the cell insulating layer 132, and the through plug 188 is electrically connected to the first wiring portion 230 of the circuit region 200 outside the gate stacking structure 120 or by penetrating the gate stacking structure 120.

In some embodiments, the gate contact portion 184 penetrate the cell insulating layer 132 and the gate electrode 130, and extends into the first wiring portion 230 in the circuit region 200. For example, the gate contact portion 184 has a connection portion connected to a connection gate electrode t 130 in the gate stacking structure 120. In addition, the gate contact portion 184 is insulated from the remaining gate electrodes 130 by an insulating material.

The connection wire 190 is positioned in the cell array region 102 and/or the connection region 104. The bit line 182, the source contact portion 186, and/or the through plug 188 are electrically connected to the connection wire 190. For example, the gate contact portion 184, the source contact portion 186, and/or the through plug 188 are connected to the connection wire 190 through the contact via 180a. However, embodiments are not necessarily limited thereto.

FIG. 1 illustrates that the connection wire 190 is provided as a single layer and on the same plane as the bit line 182, and a second insulating layer 192 is disposed in portions between the connection wires 190. However, this is shown for convenience of illustration. Accordingly, the connection wire 190 may include a plurality of wiring layers and contact vias for electrical connection with the bit line 182, the gate contact portion 184, the source contact portion 186, and/or the through plug 188.

The bit line 182 is connected to the channel structure CH, the gate electrode 130, the horizontal conductive layers 112 and 114, and/or the second substrate 110, and is electrically connected to the circuit element 220 of the circuit region 200 by the second wiring portion 180 and the first wiring portion 230.

FIG. 1 illustrates that the gate contact portion 184, the source contact portion 186, and/or the through plug 188 have an inclined side surface so that the width becomes narrower as it approaches the second substrate 110 due to a high aspect ratio when viewed in a cross-sectional view, and a bent portion is provided at a boundary between the plurality of gate stacking structures 120a and 120b. However, embodiments are not necessarily limited thereto. In some embodiments, the gate contact portion 184, the source contact portion 186, and/or the through plug 188 do not have a bent portion at the boundary between the plurality of gate stacking structures 120a and 120b. Various other variations are possible.

As mentioned above, in an embodiment, the channel layer 140 may have a single crystal structure or a quasi-single crystal structure. The crystal structure of the channel layer 140 will be described in more detail with reference to FIGS. 3 to 5.

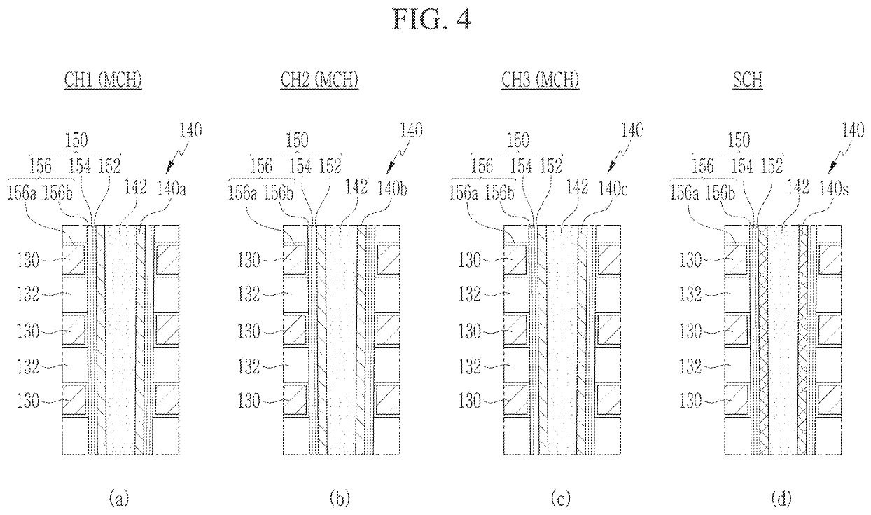

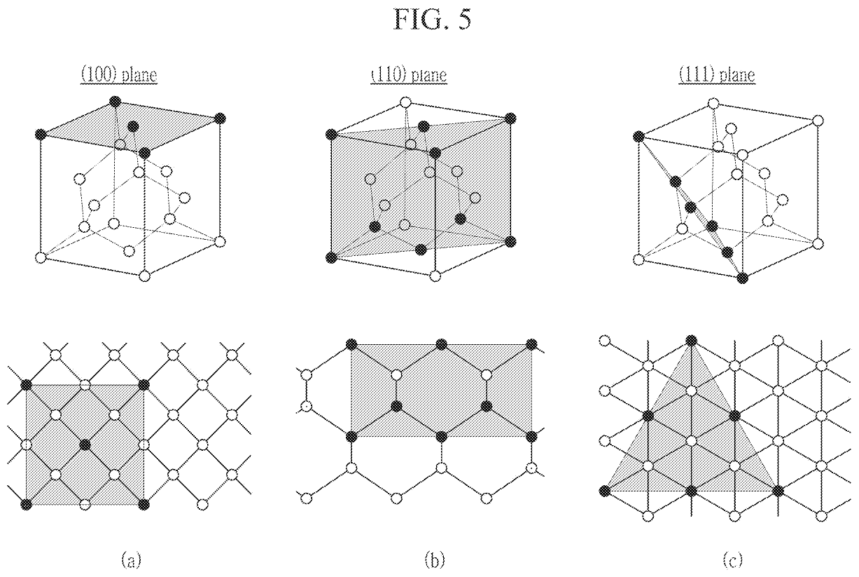

FIG. 3 is an enlarged top plan view that illustrates a part of the cell array region 102 of the semiconductor device 10 shown in FIG. 1, and FIG. 4 is an enlarged cross-sectional view that illustrates a part of the plurality of channel structures CH in the semiconductor device 10 shown in FIG. 1. FIG. 5 illustrates crystal planes of a channel layer in the semiconductor device shown in FIG. 1. A part of a first channel structure CH1 is shown in (a) of FIG. 4, a part of a second channel structure CH2 is shown in (b) of FIG. 4, a part of a third channel structure CH3 is shown in (c) of FIG. 4, and a part of a sub-channel structure SCH is shown in FIG. 4 (d).

Referring to FIGS. 3 and 4, in an embodiment, channel layers 140 of a plurality of channel structures CH may have a single crystal structure or a quasi-single crystal structure. A single crystal structure refers to a crystal structure that has one crystal orientation and no grain boundary. A quasi-single crystal structure refers to a crystal structure that has one crystal orientation overall, but locally has defects, such as missing atoms or twin boundaries, in a limited area. A quasi-single crystal structure may be referred to as a similar single crystal structure, etc. For example, the channel layer 140 may have a single crystal structure or quasi-single crystal structure by metal-induced crystallization or metal-induced lateral crystallization.

When the channel layer 140 has a single crystal structure or quasi-single crystal structure, electrical resistance of the channel layer 140 can be reduced. As a result, cell current can be increased and performance of the semiconductor device 10 can be increased. In particular, when a number of gate electrodes 130 increases, cell current effectively increases.

In an embodiment, the plurality of channel structures CH include a first channel structure CH1 that includes a first channel layer 140a, and a plurality of second channel structures CH2 adjacent to the first channel structure CH1 and that including second channel layers 140b. For example, the first channel layer 140a and the second channel layers 140b may have a single crystal structure or a quasi-single crystal structure while having the same crystal orientation.

The plurality of second channel structures CH2 are positioned at a shortest distance from the first channel structure CH1, or a are plurality of channel structures that are positioned at the shortest distance from the first channel structure CH1. For example, FIG. 3 illustrates that the second channel structures CH2 are positioned at each corner of a rectangle centered on the first channel structure CH1. For example, FIG. 3 illustrates that a number of the plurality of second channel structures CH2 adjacent to the first channel structure CH1 is four. However, embodiments are not necessarily limited thereto, and in other embodiments, the number of the plurality of second channel structures CH2 adjacent to the first channel structure CH1 may be two, three, or five or more, depending on an arrangement of the plurality of channel structures CH. For example, the number of the plurality of second channel structures CH2 adjacent to the first channel structure CH1 may be 24 or less, such as 12 or less, but embodiments are not necessarily limited thereto.

In addition, the plurality of channel structures CH further include a plurality of third channel structures CH3 that include third channel layers 140c. The third channel layers 140c may have a single crystal structure or a quasi-single crystal structure, while having the same crystal orientation as the first channel layer 140a and the second channel layers 140b. The plurality of third channel structures CH3 include any channel structure whose third channel layer 140c has the same crystal orientation as the first channel layer 140a and the second channel layer 140b while being not positioned adjacent to the first channel structure CH1.

For example, the plurality of channel structures CH, such as the first to third channel structures CH1, CH2 and CH3, that include channel layers 140, such as the first to third channel layers 140a, 140b and 140c, that have the same crystal orientation may be referred to as a main channel structure MCH. The main channel structure MCH refers to a channel structure of the plurality of channel structures that has a largest number of channel structures CH.

In an embodiment, the plurality of channel layers 140 in the plurality of channel structures CH have the same crystal orientation while having a single crystal structure or quasi-single crystal structure by a metal-induced crystallization process or a metal-induced lateral crystallization process. This will be described in more detail below with respect to a manufacturing method of the semiconductor device 10. Accordingly, the first to third channel structures CH1, CH2 and CH3, which each include first to third channel layers 130a, 130b and 130c that have the same crystal orientation, are included in the largest number of the plurality of channel structures CH.

In some cases, the plurality of channel structures CH includes a sub-channel structure SCH that has a sub-channel layer 140s. The sub-channel layer 140s refers to a channel layer that has a single crystal structure or a quasi-single crystal structure, but has a crystal orientation that differs from a crystal orientation of the first to third channel layers 140a, 140b, and 140c. The sub-channel structure SCH refers to a channel structure that includes fewer channel structures CH than the main channel structure MCH. Although FIG. 3 illustrates the sub-channel structure SCH for clear understanding, in some embodiments, the sub-channel structure SCH is omitted.

In an embodiment, a ratio of a number of the main channel structures MCH to a total number of the plurality of channel structures CH exceeds 50%. For example, the ratio of the number of the main channel structures MCH to the total number of the plurality of channel structures CH is 80% or more. For example, the ratio of the number of the main channel structures MCH to the total number of the plurality of channel structures CH is 90% or more. This is because a crystallization process was used that allows the channel layers 140 in the plurality of channel structures CH to have the same crystal orientation.

A ratio of a number of sub-channel structures SCH to the total number of the plurality of channel structures CH is less than 50%. For example, the ratio of the number of sub-channel structures SCH to the total number of the plurality of channel structures CH is 20% or less. For example, the ratio of the number of sub-channel structures SCH to the total number of the plurality of channel structures CH is 10% or less.

In an embodiment, the plurality of main channel layers in the plurality of main channel structures MCH, such as the first channel layer 140a, the plurality of second channel layers 140b, and/or the plurality of third channel layers 140c, have the same crystal orientation. Accordingly, the first channel structure CH1, the plurality of second channel structures CH2, and/or the plurality of third channel structures CH3 have substantially the same or similar properties. For example, the first channel layer 140a, the plurality of second channel layers 140b, and/or the plurality of third channel layers 140c are crystallized to have substantially the same or similar degree of crystallization, have substantially the same or similar number of defects, and have substantially similar carrier mobilities. Accordingly, the plurality of main channel structures MCH have similar cell properties, and the first channel layer 140a, the plurality of second channel layers 140b, and/or the plurality of third channel layers 140c are stably crystallized in a crystallization process.

According to an embodiment, a cell current difference in a plurality of memory cells in the semiconductor device 10 can be reduced, thereby increasing cell properties.

For reference, in a conventional art, the channel layers in the plurality of channel structures have different crystal orientations, and the plurality of channel structures have different cell properties. For example, the crystallization or defect levels of the channel layers in the plurality of channel structures are different, and carrier mobility may be different due to different crystal orientations. Moreover, even within a channel layer in one channel structure, portions that have different properties may be provided. For example, there may be a portion that does not have a single crystal structure or a quasi-single crystal structure because a path of the crystallization-inducing metal is obstructed in the channel layer. In addition, a crystallization process might not smoothly occur in some of the plurality of channel structures. For example, crystallization may proceed differently due to a difference in crystallization speed depending on the crystal orientation, or there may be a portion where crystallization is not smoothly performed, depending on the crystal orientation. On the other hand, in an embodiment, since the plurality of main channel structures MCH are crystallized to have the same crystal orientation, which thereby effectively suppresses or prevents the above-described situations.

For example, an entire portion of the channel layer 140 in the channel structure CH has the same crystal orientation. This is because the entire portion of the channel layer 140 is stably crystallized by performing the metal-induced crystallization process or the metal-induced lateral crystallization process to have the same crystal orientation as described above.

As described above, in an embodiment, the channel structure CH includes a plurality of channel portions CHa and CHb positioned in an up and down direction and that penetrate the plurality of gate stacking structures 120a and 120b, respectively. For example, each of the first channel layer 140a, the second channel layer 140b, the third channel layer 140c, and/or the sub-channel layer 140s has the same crystal orientation overall in the plurality of channel portions CHa and CHb.

In an embodiment, in a plan view, the crystal plane of the first channel layer 140a, the second channel layer 140b, and/or the third channel layer 140c may be a (100) plane shown in (a) of FIG. 5, or a (110) plane shown in (b) of FIG. 5, or a (111) plane shown in (c) of FIG. 5. For example, when the crystal plane of the channel layer 140 is a (100) plane in a plan view, the plurality of (100) planes are stacked sequentially in an elongation direction of the channel structure CH (in the Z-axis direction in the drawing) in a plan view. When the crystal plane of the channel layer 140 is a (110) plane in a plan view, the plurality of (110) planes are stacked sequentially in the elongation direction of the channel structure CH in a plan view. When the crystal plane of the channel layer 140 includes a (111) plane in a plan view, the plurality of (111) planes are stacked sequentially in the elongation direction of the channel structure CH in a plan view.

For example, in a plan view, the crystal plane of the first channel layer 140a, the second channel layer 140b, and/or the third channel layer 140c is the (100) plane shown in (a) of FIG. 5. Accordingly, excellent carrier mobility can be obtained in the first channel layer 140a, the second channel layer 140b, and/or the third channel layer 140c.

In some embodiments, in a plan view, the crystal plane of the first channel layer 140a, the second channel layer 140b, and/or the third channel layer 140c is the (111) plane shown in (c) of FIG. 5. A diffusion direction of the crystallization-inducing metal varies depending on the crystal plane. When the crystal plane of the first channel layer 140a, the second channel layer 140b, and/or the third channel layer 140c is a (111) plane, the crystallization-inducing metal can easily move according to the elongation direction of the channel structure CH (Z-axis direction in the drawing) in the metal-induced crystallization process or the metal-induced lateral crystallization process. Accordingly, a crystallization speed is faster. However, embodiments are not necessarily limited thereto. In some embodiments, in a plan view, the first channel layer 140a, the second channel layer 140b, and/or the third channel layer 140c have various other crystal planes.

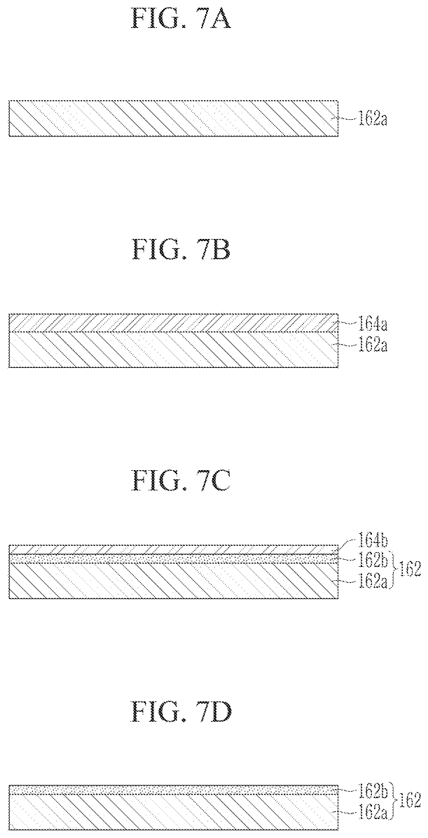

The crystal plane of the first channel layer 140a, the second channel layer 140b, and/or the third channel layer 140c is determined by the crystal plane of a surface of a metal-containing substrate 162 (see FIGS. 7C and 7D) used in the metal-induced crystallization process or the metal-induced lateral crystallization process. This will be described in more detail with reference to a manufacturing method of the semiconductor device 10.

In an embodiment, the channel layer 140 includes a compound portion 140f (see FIG. 2) that includes a metal-semiconductor compound at a lower portion or a bottom portion of the channel structure CH. The compound portion 140f is formed by a metal-induced crystallization process or a metal-induced lateral crystallization process.

For example, the compound portion 140f includes a metal-semiconductor compound in which a metal, such as a crystallization-inducing metal used in a metal-induced crystallization process or a metal-induced lateral crystallization process, and a semiconductor material in the channel layer 140 are chemically bonded. For example, the crystallization-inducing metal that remains at the lower portion or the bottom portion of the channel structure CH after the metal-induced crystallization process or the metal-induced lateral crystallization process configures the compound portion 140f. However, in some embodiments, a process of removing the compound portion 140f or lowering a content of the crystallization-inducing metal is additionally performed.

In an embodiment, the channel layer 140 includes silicon, and the compound portion 140f includes a metal silicide. For example, the crystallization-inducing metal includes one or more of nickel (Ni), cobalt (Co), palladium (Pd), or copper (Cu), etc., and the compound portion 140f includes at least one of nickel silicide, cobalt silicide, palladium silicide, or copper silicide, etc. However, embodiments are not necessarily limited thereto, and in other embodiments, the material of the crystallization-inducing metal and/or the compound portion 140f can variously change.

Portions of the channel layer 140 other than the compound portion 140f include a semiconductor material. For example, other portions of the channel layer 140 include a semiconductor material layer that includes or is made of a semiconductor material. Since the other portions of the channel layer 140 are adjacent to the gate electrode 130 and are directly related to an operation of the memory cell, the other portions either might not contain the crystallization-inducing metal or may contain the crystallization-inducing metal at a very low content, in consideration of performance of the memory cell. For this, in a metal-induced crystallization process or a metal-induced lateral crystallization process, process conditions can be adjusted so that the crystallization-inducing metal does not remain or remains at a low content in the other portions of the channel layer 140. In some embodiments, a process of removing the crystallization-inducing metal that remains in the other portions of the channel layer 140, or of reducing the content of the crystallization-inducing metal, is additionally performed before or after the metal-induced crystallization process or the metal-induced lateral crystallization process. For example, the other portions of the channel layer 140 do not include the crystallization-inducing metal.

According to an embodiment, the channel layer 140 has a single crystal structure or a quasi-single crystal structure that increases cell current. For example, the plurality of channel layers 140 in the plurality of channel structures CH have the same crystal orientation. Accordingly, the plurality of channel structures CH have uniform cell properties, and defects of the semiconductor device 10 are reduced by the stably crystallized channel layer 140. As a result, performance and productivity of the semiconductor device 10 are increased.

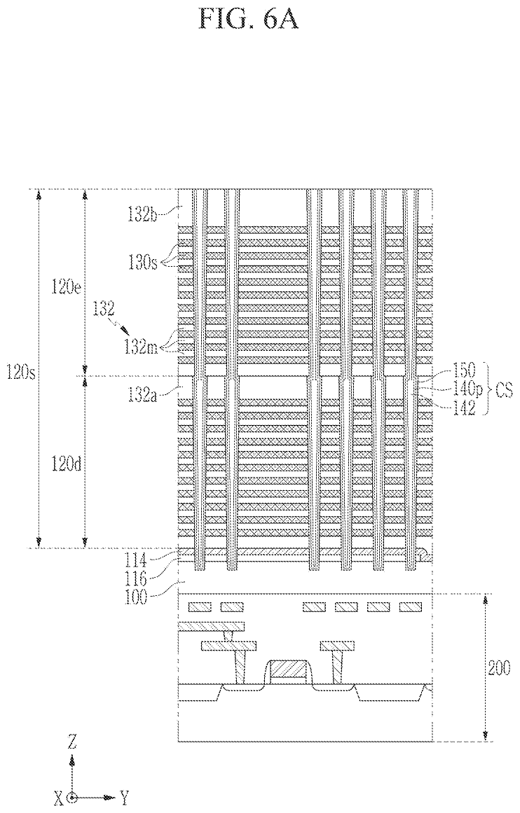

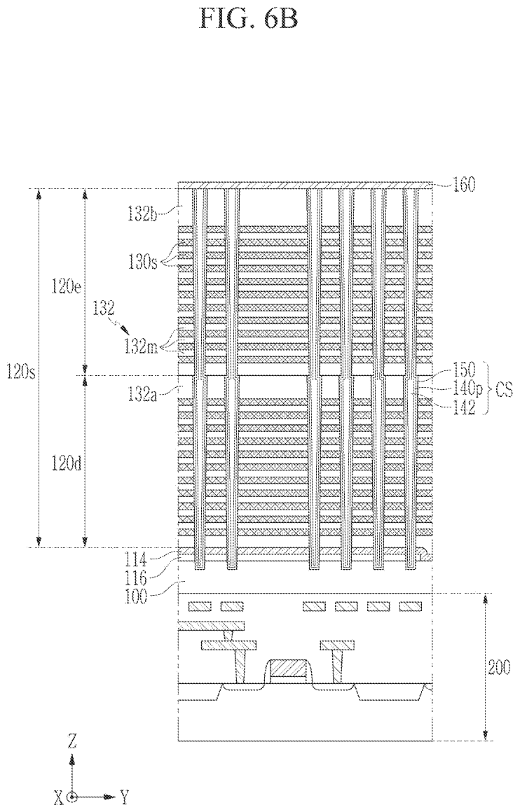

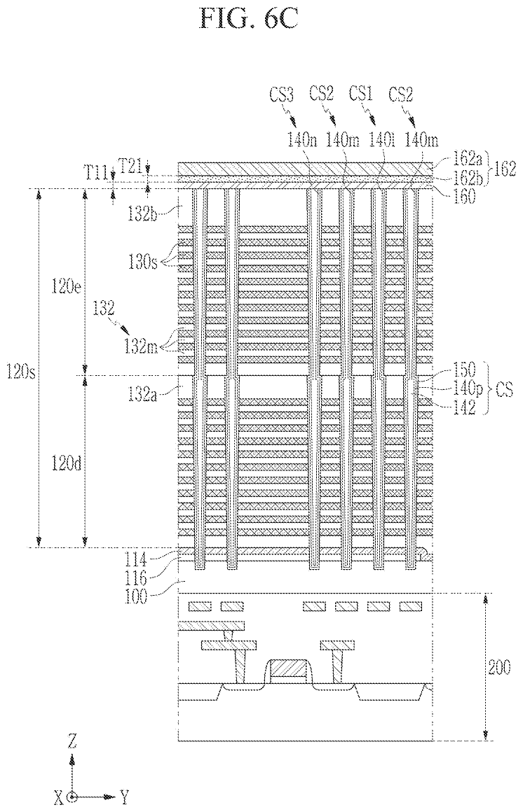

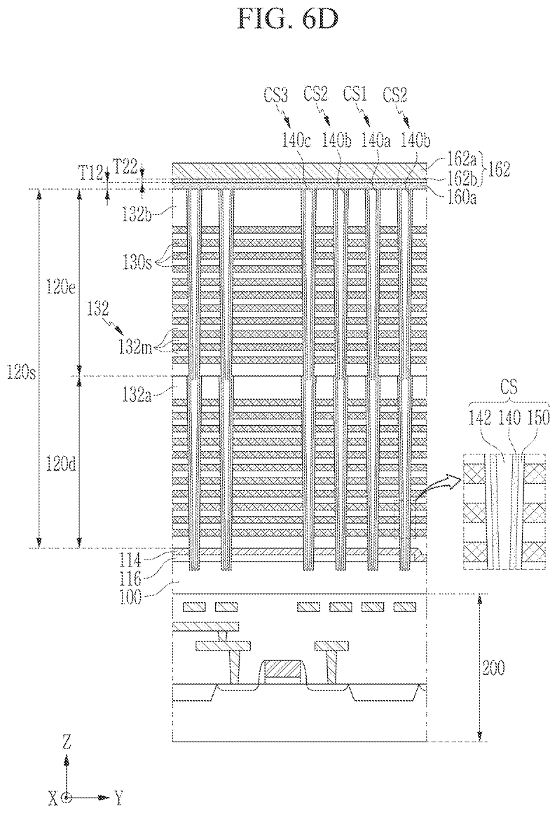

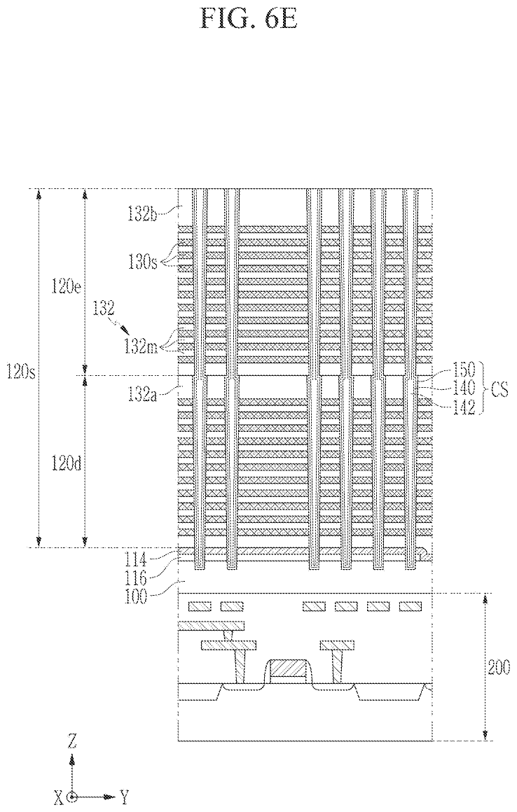

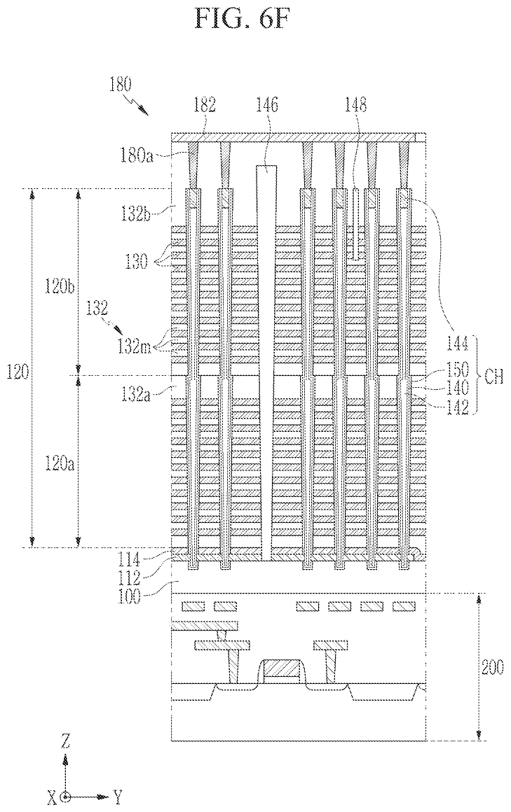

An example of a manufacturing method of the semiconductor device 10 that has the above-described structure will be described in detail with reference to FIGS. 6A to 6F and 7A to 7D together with FIGS. 1 to 5. Detailed descriptions of parts that have already been described are omitted or summarized, and parts that have not been described will be described in detail.

FIG. 6A to 6F are partial cross-sectional views that illustrate a manufacturing method of a semiconductor device according to an embodiment. FIG. 6A to 6F illustrates a portion that corresponds to a left portion of FIG. 1. Hereinafter, a manufacturing method of a semiconductor device 10 will be mainly described for a gate stacking structure 120, a channel structure CH, and a separation structure 146 in the cell region 100.

As shown in FIG. 6A, in an embodiment, a second substrate 110, a horizontal insulating layer 116, a second horizontal conductive layer 114, and a stacking structure 120s are formed on a circuit region 200. In addition, a preliminary channel structure CS that penetrates the stacking structure 120s is formed.

The second substrate 110 is formed on the circuit region 200, and the horizontal insulating layer 116 and the second horizontal conductive layer 114 are formed on the second substrate 110. The stacking structure 120s is formed by alternately stacking the interlayer insulating layer 132m and a sacrificial insulating layer 130s on the second horizontal conductive layer 114. For example, upper insulating layers 132a and 132b are positioned at an upper portion of each stacking structure 120s.

The sacrificial insulating layer 130s is a layer to be replaced with a gate electrode 130 through a subsequent process, and at least a part of the horizontal insulating layer 116 is replaced with a first horizontal conductive layer 112 through a subsequent process. For example, the sacrificial insulating layer 130s is formed to correspond to a portion where the gate electrode 130 is to be formed, and the horizontal insulating layer 116 includes a portion where the first horizontal conductive layer 112 is to be formed.

The horizontal insulating layer 116 and/or the sacrificial insulating layer 130s include or are formed of a material that differs from that of the interlayer insulating layer 132m. For example, the interlayer insulating layer 132m includes at least one of silicon oxide, silicon nitride, silicon oxynitride, or a low dielectric constant material, etc., and the horizontal insulating layer 116 and/or the sacrifice insulating layer 130s include one of silicon, silicon oxide, silicon carbide, or silicon nitride, etc., and include or are made of a material that differs from the material of the interlayer insulating layer 132m.

A penetrating portion that penetrates the stacking structure 120s is formed that corresponds to a portion where a channel structure CH in FIG. 6D is to be formed, and the preliminary channel structure CS is formed in the penetrating portion. For example, a gate dielectric layer 150, a preliminary channel layer 140p, and a core insulating layer 142 are sequentially formed that fill the penetrating portion. For example, a first blocking layer 156a of the gate dielectric layer 150 is not formed, but may be formed later in another process. The preliminary channel structure CS does not have a channel pad 144.

In an embodiment, the preliminary channel layer 140p includes an amorphous semiconductor layer that has an amorphous structure. For example, the preliminary channel layer 140p includes an amorphous silicon layer. Accordingly, the preliminary channel layer 140p can be easily formed through a process such as deposition.

In an embodiment, a bottom surface of the preliminary channel structure CS is positioned in the second substrate 110. Accordingly, the channel structure CH and the horizontal conductive layers 112 and 114 can be stably connected. For example, a process margin is secured. However, embodiments are not limited necessarily thereto, and numerous variations are possible in other embodiments.

In an embodiment, the stacking structure 120s includes a plurality of stacking structures 120d and 120e that are sequentially stacked on a semiconductor substrate 110s, and the preliminary channel structure CS includes a plurality of channel portions that penetrate the plurality of stacking structures 120d and 120e. However, embodiments are not necessarily limited thereto.

As shown in FIG. 6B, in an embodiment, an amorphous semiconductor layer 160 is formed on an upper surface of the preliminary channel structure CS or an upper surface of the stacking structure 120s.

The amorphous semiconductor layer 160 is for forming a stable connection or for bonding with a metal-containing layer (reference numeral 162b in FIG. 6C). The crystallization process is stably performed when the preliminary channel layer 140p in the preliminary channel structure CS is stably connected to the metal-containing layer 162b. A lower surface of the amorphous semiconductor layer 160 is entirely connected to the upper surface of the preliminary channel layer 140p, and a surface of the metal-containing layer 162b is entirely connected to the upper surface of the amorphous semiconductor layer 160. The metal-containing layer 162b is stably connected to the preliminary channel layer 140p through the amorphous semiconductor layer 160 even if there is warpage of the metal-containing substrate 162 or a stacking structure 102s.

The amorphous semiconductor layer 160 can be formed by any of various processes, such as a deposition process. For example, the amorphous semiconductor layer 160 can be formed by a chemical vapor deposition process. In some embodiments, a planarization process is performed on the amorphous semiconductor layer 160 after the amorphous semiconductor layer 160 is formed. For example, the planarization process is performed by a chemical mechanical polishing (CMP) process.

However, embodiments are not necessarily limited thereto. The amorphous semiconductor layer 160 can be formed by any of various processes, or, in some embodiments, the process of forming the amorphous semiconductor layer 160 is not performed. In some embodiments, the planarization process of the amorphous semiconductor layer 160 is performed in a different process from the chemical mechanical polishing process, or the planarization process of the amorphous semiconductor layer 160 is not performed.

The amorphous semiconductor layer 160 has a thickness of 20 nm to 100 nm. When the thickness of the amorphous semiconductor layer 160 is less than 20 nm, the upper surface might not be sufficiently planarized to perfectly bond to the metal-containing layer 162b. When the thickness of the amorphous semiconductor layer 160 is greater than 100 nm, a process time of the process of forming the amorphous semiconductor layer 160 increases. However, embodiments are not necessarily limited thereto, and the thickness of the amorphous semiconductor layer 160 may have any of various values. Accordingly, in some embodiments, the amorphous semiconductor layer 160 has a thickness of less than 20 nm or greater than 100 nm.

As shown in FIG. 6C, the metal-containing layer 162b that has a single crystal structure or a quasi-single crystal structure is positioned on the amorphous semiconductor layer 160 of the stacking structure 120s). For example, the metal-containing substrate 162 is positioned on the stacking structure 120s.

The metal-containing substrate 162 includes a semiconductor substrate 162a and the metal-containing layer 162b on one side of the semiconductor substrate 162a. In this way, when the metal-containing layer 162b is formed as a part of the metal-containing substrate 162, the metal-containing layer 162b that has a single crystal structure or a quasi-single crystal structure can be easily formed. For example, the metal-containing layer 162b can be easily formed using the semiconductor substrate 162a, which has a single crystal structure or a quasi-single crystal structure. The metal-containing substrate 162 may be manufactured by any of various methods.

An example of a manufacturing method of the metal-containing substrate 162 will be described in more detail with reference to FIGS. 7A to 7D. FIG. 7A to 7D are cross-sectional views that illustrate an example of a manufacturing process of the metal-containing substrate 162 used in a manufacturing method of the semiconductor device 10 according to an embodiment.

As shown in FIG. 7A, in an embodiment, a semiconductor substrate 162a is prepared. For example, a semiconductor substrate 162a has a single crystal structure or a quasi-single crystal structure, such as an epitaxial structure, and includes a semiconductor material. For example, the semiconductor substrate 162a is a single crystal silicon substrate or a quasi-single crystal silicon substrate, such as an epitaxial silicon substrate, that includes a single crystal silicon or a quasi-single crystal silicon, such as epitaxial silicon.

As shown in FIG. 7B, a metal layer 164a is formed on the semiconductor substrate 162a. For example, the metal layer 164a includes a single metal layer that includes a metal. For example, the metal layer 164a includes a crystallization-inducing metal such as nickel, cobalt, palladium, or copper. For example, the metal layer 164a is formed by physical vapor deposition (PVD). Accordingly, the metal layer 164a that includes a crystallization-inducing metal can be easily formed. However, embodiments are not necessarily limited thereto. For example, the metal layer 164a includes a plurality of metals or a material other than a metal. The metal layer 164a can be formed by any of various processes other than a physical vapor deposition process.

As shown in FIG. 7C, a metal-containing layer 162b is formed by performing a heat treatment process that diffuses the metal in the metal layer 164a to one surface of the semiconductor substrate 162a.

For example, an annealing process is performed at a temperature of 700 degrees Celsius or higher, such as 700 degrees Celsius to 1000 degrees Celsius. This is because the metal-containing layer 162b can be stably formed in this temperature range. However, embodiments are not necessarily limited thereto, and the temperature of the heat treatment process for forming the metal-containing layer 162b differs in other embodiments.

The metal in the metal layer 164a diffuses into a part of the semiconductor substrate 162a and chemically combines with the semiconductor material in the semiconductor substrate 162a to form the metal-containing layer 162b. Accordingly, a crystal structure of the metal-containing layer 162b is the same as a crystal structure of the semiconductor substrate 162a. For example, the metal-containing layer 162b has a single crystal structure or a quasi-single crystal structure, such as an epitaxial structure. In some embodiments, the metal-containing layer 162b includes an epitaxial layer formed by epitaxial growth on one surface of the semiconductor substrate 162a. The metal-containing layer has a quasi-single crystal structure, such as an epitaxial structure.

In an embodiment, the metal-containing layer 162b includes at least one of nickel silicide (e.g., NiSi₂), cobalt silicide, palladium silicide, or copper silicide, etc. However, embodiments are not necessarily limited thereto, and in other embodiments, the crystallization-inducing metal and/or the material of the metal-containing layer 162b can change.

In an embodiment, a residual metal layer 164b remains on the metal-containing layer 162b. As shown in FIG. 7D, the residual metal layer 164b positioned on the metal-containing substrate 162 is removed. For example, the residual metal layer 164b is removed by at least one of a chemical mechanical polishing process, a dry etching process, or a wet etching process.

By removing the residual metal layer 164b after forming the residual metal layer 164b, the metal-containing layer 162b is stably positioned on a surface of the semiconductor substrate 162a. However, embodiments are not necessarily limited thereto. In other embodiments, no residual metal layer 164b remains after the metal-containing layer 162b is formed, and a process of removing the residual metal layer 164b is not performed.

In an embodiment, the metal-containing layer 162b in the metal-containing substrate 162 has a thickness of 10 nm to 100 nm. When the thickness of the metal-containing layer 162b is less than 10 nm, the metal in the metal-containing layer 162b might not be stably diffused to the preliminary channel layer 140p. When the thickness of the metal-containing layer 162b is greater than 100 nm, a process time for forming the metal-containing layer 162b increases. However, embodiments are not necessarily limited thereto. In other embodiments, the thickness of the metal-containing layer 162b is less than 10 nm or greater than 100 nm.

As shown in FIG. 6D, the plurality of channel layers 140 are formed by performing a heat treatment process that crystallizes a plurality of preliminary channel layers 140p in the plurality of preliminary channel structures CS. For example, in a heat treatment process, the stacking structure 120s and the metal-containing substrate 162 are bonded, and the amorphous semiconductor layer (reference numeral 160 in FIG. 6C) becomes a crystalline semiconductor layer 160a that has single crystal structure or a quasi-single crystal structure.

In an embodiment, the preliminary channel layer 140p is metal-induced crystallized or metal-induced lateral crystallized by a heat treatment crystallization process that forms the channel layer 140. For example, as the metal in the metal-containing layer 162b diffuses into the preliminary channel layer 140p through the amorphous semiconductor layer 160, allowing the preliminary channel layer 140p to be metal-induced crystallized or metal-induced laterally crystallized by the heat treatment process. Accordingly, the preliminary channel layer 140p crystallizes into the channel layer 140 that has a single crystal structure or a quasi-single crystal structure. For example, the channel layer 140 is crystallized from the metal-containing layer 162b, which has a single crystal structure or a quasi-single crystal structure and whose surface includes substantially one crystal plane. Accordingly, the crystal orientation of the plurality of preliminary channel layers 140p are determined according to the crystal plane of the surface of the metal-containing layer 162b.

For example, the crystal plane of the surface of the metal-containing layer 162b is one of a (100) plane, a (110) plane or a (111) plane. The plane of the preliminary channel layer 140p that faces the surface of the metal-containing layer 162b, such as the XY plane in the drawing, crystallizes to have the same crystal plane as the surface of the metal-containing layer 162b. Accordingly, in a plan view, the crystal plane of the channel layer 140 is one of the (100) plane, the (110) plane, or the (111) plane. For example, the crystal plane of the surface of the metal-containing layer 162b is the (100) plane, and the crystal plane of the channel layer 140 is the (100) plane in a plan view. For another example, the crystal plane of the surface of the metal-containing layer 162b is the (111) plane, and the crystal plane of the channel layer 140 is the (111) plane in a plan view.

For example, as shown in FIG. 6C, the plurality of preliminary channel structures CS include a first preliminary channel structure CS1 that includes a first preliminary channel layer 1401, and a plurality of second preliminary channel structures CS2 adjacent to the first preliminary channel structure CS1 and that include second preliminary channel layers 140m, respectively. The plurality of preliminary channel structures CS also include a plurality of third preliminary channel structures CS3 that include third preliminary channel layers 140n. As shown in FIG. 6D, the first to third preliminary channel layers 1401, 140m and 140n in FIG. 6C crystallize to have the same crystal orientation by metal-induced crystallization or metal-induced lateral crystallization, thereby each forming the first to third channel layers 140a, 140b and 140c, respectively. The first to third preliminary channel structures CS1, CS2, and CS3 correspond to the first to third channel structures CH1, CH2 and CH3 in FIG. 3, respectively.

For clarity and simplicity of illustration, FIGS. 6C to 6D illustrate that the second preliminary channel structure CS2 is positioned on both sides of the first preliminary channel structure CS1, and the third preliminary channel structure CS3 is positioned on one side of a second preliminary channel structure CS2.

For example, the plurality of preliminary channel layers 1401, 140m and 140n in the plurality of preliminary channel structures CS respectively crystallize into the channel layers 140a, 140b and 140c that have the same crystal orientation. For example, an entire portion of the channel layer 140 in each of the channel structures CH has the same crystal orientation. The entire portion of the channel layer 140 has been stably crystallized by performing a metal-induced crystallization process or a metal-induced lateral crystallization process using the metal-containing layer 162b with a single crystal structure or a quasi-single crystal structure as described above, and thus, the channel layer 140 has the same crystal orientation. In some cases, a sub-channel layer (reference numeral 140s in FIG. 4) is formed that has a different crystal orientation from a crystal orientation of the first to third channel layers 140a, 140b and 140c.

In an embodiment, the heat treatment process is suitable for metal-induced crystallization or metal-induced lateral crystallization. For example, a heat treatment process is performed that forms a metal-semiconductor compound that contains metal in at least a part of the amorphous semiconductor layer 160 and/or the preliminary channel layer 140p, and a heat treatment process is performed for metal-induced crystallization or metal-induced lateral crystallization.

For example, the heat treatment process that forms the metal-semiconductor compound is performed at a temperature, such as less than 500 degrees Celsius, such as 300 degrees Celsius to 400 degrees Celsius, lower than the heat treatment crystallization process. In an annealing process, the crystallization-inducing metal in the metal-containing layer 162b diffuses into the amorphous semiconductor layer 160 and/or the preliminary channel layer 140p and chemically bonds to the semiconductor material of the amorphous semiconductor layer 160 and/or the preliminary channel layer 140p. Accordingly, a compound portion that includes a metal-semiconductor compound, such as a metal silicide, in which a crystallization-inducing metal and semiconductor material, such as silicon, are chemically bonded is formed in the amorphous semiconductor layer 160 and/or the preliminary channel layer 140p. For example, the compound portion is formed in a portion of the amorphous semiconductor layer 160 and/or the preliminary channel layer 140p, such as an upper portion of the amorphous semiconductor layer 160 and/or an upper portion of the preliminary channel layer 140p. For example, the metal in the metal-containing layer 162b might not diffuse into the cell insulating layer 132.

The heat treatment crystallization process is performed at a temperature, such as 500 degrees Celsius or higher, or 500 degrees Celsius to 700 degrees Celsius, that is higher than the temperature of the heat treatment process that forms the metal-semiconductor compound. For example, the heat treatment crystallization process is performed at a heat treatment temperature at which metal-induced crystallization or metal-induced lateral crystallization is possible.

In an embodiment, a heat treatment process that forms a metal-semiconductor compound and a heat treatment crystallization process can be continuously performed. In other embodiments, a heat treatment process that forms a metal-semiconductor compound and a heat treatment crystallization process are performed as separate processes. In an embodiment, a process of removing the metal-containing substrate 162, shown in FIG. 6E, is performed between the heat treatment process that forms the metal-semiconductor compound and the heat treatment crystallization process. Other variations are possible in other embodiments.

In an embodiment, during the metal-induced crystallization process or the metal-induced lateral crystallization process, the metal in the metal-containing layer 162b diffuses into the preliminary channel layer 140p through the amorphous semiconductor layer 160. Accordingly, a thickness T12 of a crystalline semiconductor layer 160a after the metal-induced crystallization process or the metal-induced lateral crystallization process is greater than a thickness T11 of the amorphous semiconductor layer 160 before the metal-induced crystallization process or the metal-induced lateral crystallization process. A thickness T22 of the metal-containing layer 162b after the metal-induced crystallization process or the metal-induced lateral crystallization process is less than the thickness T21 of the metal-containing layer 162b before the metal-induced crystallization process or the metal-induced lateral crystallization process. However, embodiments are not necessarily limited thereto. The thickness of the metal-containing layer 162b and/or the thickness of the amorphous semiconductor layer 160 might not be changed by the metal-induced crystallization process or the metal-induced lateral crystallization process. In some embodiments, the thickness of the metal-containing layer 162b and/or the thickness of the amorphous semiconductor layer 160 change differently from those described above by the metal-induced crystallization process or the metal-induced lateral crystallization process.

In an embodiment, a heat treatment process for metal-induced crystallization or the metal-induced lateral crystallization process are performed before forming the channel pad 144. A heat treatment process is included in a process of forming the channel pad 144. If a process of forming the channel pad 144 is performed before a heat treatment process for metal-induced crystallization or the metal-induced lateral crystallization process, the preliminary channel layer 140p is crystallized by the heat treatment process when forming the channel pad 144. The channel layer 140 that has desired properties might not be formed. However, embodiments are not necessarily limited thereto.

As shown in FIG. 6E, the metal-containing substrate 162 is removed from the stacking structure 120s. In addition, the crystalline semiconductor layer 160a is removed.

The metal-containing substrate 162 can be removed by any of various processes. For example, the metal-containing substrate 162 can be removed by at least one of a chemical mechanical polishing process, a dry etching process, or a wet etching process. For example, after a part of the metal-containing substrate 162 is removed through a chemical mechanical polishing process, the remaining part of the metal-containing substrate 162 is removed through a wet etching process. Accordingly, the metal-containing substrate 162 is stably removed.

The crystalline semiconductor layer 160a can be removed by any of various processes. For example, the crystalline semiconductor layer 160a can be removed by at least one of a chemical mechanical polishing process, a dry etching process, or a wet etching process.

According to embodiments, after removing a part of the cell insulating layer 132 at an upper surface of the stacking structure 120s, such as a part or all of the upper insulating layer 132b, a part of the cell insulating layer 132, such as a part or all of the upper insulating layer 132b, is formed again at the corresponding portion. Accordingly, cell properties are increased by removing a portion where the properties of the cell insulating layer 132 have been changed by the metal-induced crystallization process or the metal-induced crystallization process. However, embodiments are not necessarily limited thereto, and in other embodiments, the cell insulating layer 132 provided in the stacking structure 120s before the metal-induced crystallization process or the metal-induced crystallization process is maintained as is. This is because the metal in the metal-containing substrate 162 does not diffuse easily into the cell insulating layer 132 by default.

As shown in FIG. 6F, a channel structure CH is formed by forming the channel pad 144 connected to the semiconductor layer 140. In addition, the sacrificial insulating layer 130s in FIG. 6C is replaced with a gate electrode 130, and a separation structure 146 is formed.

An opening is formed in a region that corresponds to the separation structure 146 that penetrates the stacking structure 120s. The sacrificial insulating layer 130s is selectively removed by an etching process, such as a wet etching process, through the opening. In addition, the gate electrode 130 is formed by filling a conductive material in a portion from which the sacrificial insulating layer 130s was removed. Accordingly, the region where the sacrificial insulating layer 130s was positioned is replaced with the gate electrode 130. For example, a process of forming the first blocking layer 156a is further performed before the process of filling the conductive material to form the gate electrode 130. For example, an opening is formed to expose the horizontal insulating layer 116. In an etching process through the opening, at least a part of the horizontal insulating layer 116 is removed, and a material in the first horizontal conductive layer 112 is buried to form the first horizontal conductive layer 112.

The separation structure 146 is formed by filling the opening with an insulating material, etc. In addition, the first wiring portion 180, such as the bit line 182 connected to the channel structure CH, is further formed.

An upper separation region 148 is further formed on a part of the gate stacking structure 120, according to embodiments. The upper separation region 148 is formed by forming an upper separation opening by an etching process that uses a mask layer and depositing an insulating material in the upper separation opening. The process of forming the upper separation region 148 may be performed before or after the metal-induced crystallization process or the metal-induced lateral crystallization, before or after the process of forming the opening or separation structure 146, etc. For example, the process sequence of forming the upper separation region 148 is not limited. In some embodiments, the upper separation region 148 is not formed.

According to an embodiment, the semiconductor device 10 that includes the channel layers 140 of the plurality of channel structures CH that have the same crystal orientation for increased performance can be manufactured through an easy process. Accordingly, productivity of the semiconductor device 10 is increased.

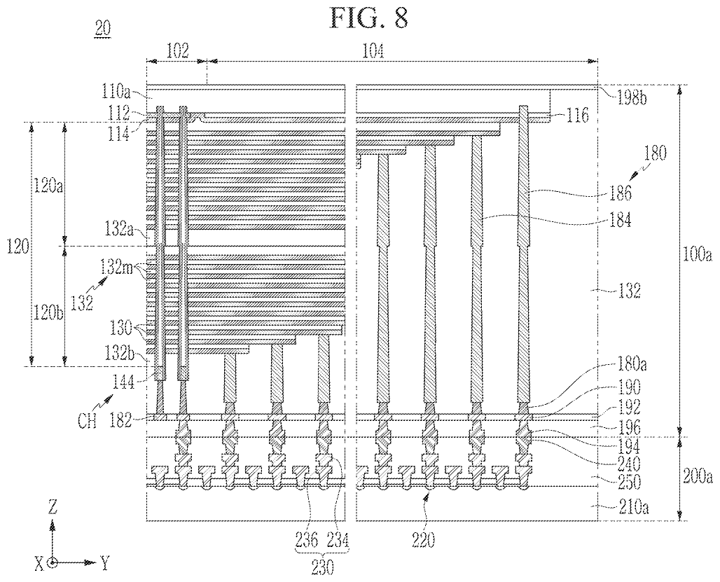

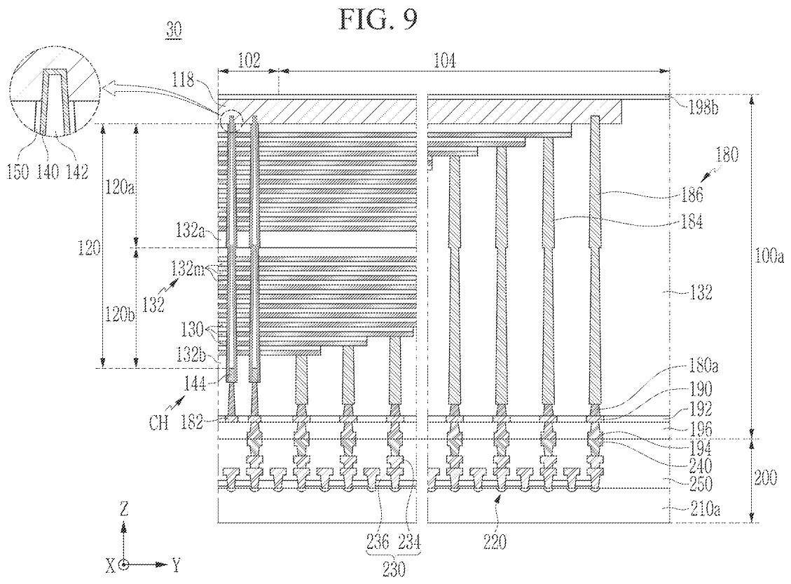

Additional embodiments that differ from the above-described embodiments and modifications thereof will be described in detail with reference to FIGS. 8 and 9. Description of components whose reference numerals are the same as or similar to those that have been described above may be omitted or summarized, except where otherwise indicated. Hereinafter, a description will be given mainly of parts that differ from the description in the above-described embodiment.

FIG. 8 is a schematic cross-sectional view of a semiconductor device 20 according to an embodiment.

Referring to FIG. 8, the semiconductor device 20 according to an embodiment has a chip to chip (C2C) structure bonded by a wafer bonding method. For example, after manufacturing a lower chip that includes a circuit region 200a formed on a first substrate 210a and manufacturing an upper chip that includes a cell region 100a formed on a second substrate 110a, the lower chip and the upper chip are bonded to manufacture the semiconductor device 20.

The circuit region 200a include the first substrate 210a, a circuit element 220, a first wiring portion 230, and a first bonding structure 240 electrically connected to the first wiring portion 230 and positioned on a surface that faces the cell region 100a. A region other than the first bonding structure 240 on the surface facing the cell region 100a is covered by a first insulating layer 250.

The cell region 100a includes the second substrate 110a, a gate stacking structure 120, a channel structure CH, a second wiring portion 180, and a second bonding structure 194 electrically connected to the second wiring portion 180 and positioned on a surface that faces the circuit region 200a. A region other than the second bonding structure 194 is covered by an insulating layer 196.

In an embodiment, the second substrate 110a is a semiconductor substrate that includes a semiconductor material. For example, the second substrate 110a is a semiconductor substrate that includes or is made of a semiconductor material, or is a semiconductor substrate on which a semiconductor layer is formed on a base substrate. For example, the second substrate 110a is made of at least one of single-crystal or polysilicon, germanium, silicon-germanium, silicon-on-insulator, or germanium-on-insulator. In some embodiments, the second substrate 110a includes a support member that includes an insulating layer or an insulating material. This is because, after bonding the cell region 100a to the circuit region 200a, the semiconductor substrate on the cell region 100a is removed, and a support member that includes an insulating layer or the insulating material is formed.

In an embodiment, the gate stacking structure 120 is sequentially stacked on the lower portion of the second substrate 110a, and the gate stacking structure 120 shown in FIG. 1 is vertically inverted. The channel structure CH penetrates the gate stacking structure 120 and also has a structure obtained by vertically inverting the channel structure CH shown in FIG. 2. Accordingly, in a cross-sectional view, the channel structure CH has inclined side surface that narrows in width from the circuit region 200a toward the second substrate 110a. In addition, the channel pad 144 and the second wiring portion 180 on the gate stacking structure 120 are positioned adjacent to the circuit region 200a.

For example, a first bonding structure 240 and/or the second bonding structure 194 include or are made of at least one of aluminum, copper, tungsten, or an alloy thereof. For example, the first and second bonding structures 240 and 194 include copper, and the cell region 100a and the circuit region 200a are bonded by copper-to-copper bonding, such as a directly contacted bonding.

Although FIG. 8 illustrates that the gate stacking structure 120 includes two gate stacking structures 120a and 120b, embodiments are not necessarily limited thereto, and in other embodiments, the gate stacking structure 120 includes one or three or more gate stacking structures. Except as otherwise described, the description of the gate stacking structure 120 and the channel structure CH described with reference to FIGS. 1 to 5, FIGS. 6A to 6F, and FIGS. 7A to 7D apply to the gate stacking structure 120 and the channel structure CH of FIG. 8. FIG. 8 illustrates as an example that a connection structure between the channel structure CH and the horizontal conductive layers 112 and 114 and/or the second substrate 110a is the same as the connection structure between the channel structure CH and the horizontal conductive layers 112 and 114 and/or the second substrate 110 shown in FIG. 1. However, embodiments are not necessarily limited thereto, and an electrical connection structure between the channel structure CH and the horizontal conductive layers 112 and 114 and/or the second substrate 110a may be variously modified in other embodiments. A modified embodiment will be described in detail with reference to FIG. 9.

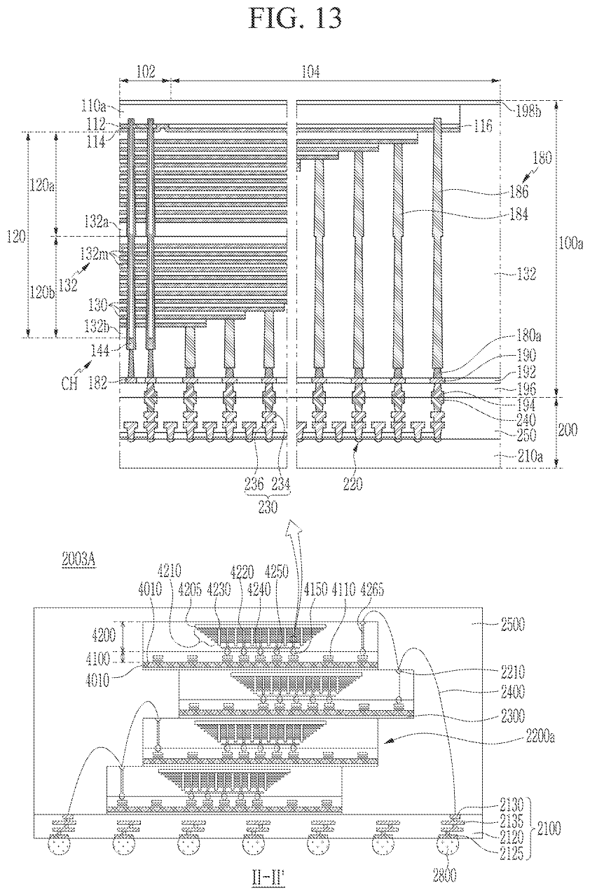

The semiconductor device 20 according to an embodiment includes input/output pads and input/output connection wires electrically connected thereto. The input/output connection wires are electrically connected to a part of the second bonding structure 194. The input/output pads are, for example, disposed on an insulating layer 198b that covers an outer surface of the second substrate 110a. In some embodiments, a separate input/output pad electrically connected to the circuit region 200a is provided. For example, the circuit region 200a and the cell region 100a are portions that respectively correspond to the first structure 1100F and the second structure 1100S of the semiconductor device 1100 in the electronic system 1000 shown in FIG. 10. The circuit region 200a and the cell region 100a are regions that respectively include a first structure 4100 and a second structure 4200 of a semiconductor chip 2200a shown in FIG. 13.

FIG. 9 is a schematic cross-sectional view of a semiconductor device according to a modified embodiment.

Referring to FIG. 9, in an embodiment, a horizontal conductive layer 118 connected to a channel structure CH covers a protruding portion of the channel structure CH. An insulating layer 198b is further positioned on an outer surface of the horizontal conductive layer 118.

In an embodiment, the channel structure CH includes an inner portion that penetrates the gate stacking structure 120, and a protruding portion that protrudes into and toward an outer portion of the horizontal conductive layer 118, shown in an upper portion of FIG. 9. The protruding portion protrudes above an upper surface of the gate stacking structure 120 that faces the horizontal conductive layer 118 in FIG. 9.

The horizontal conductive layer 118 is disposed on the entire outer surface of the protruding portion and is connected to the entire outer surface of the protruding portion. For example, the horizontal conductive layer 118 is disposed on an entire bottom surface, which is the upper surface in FIG. 9, and a side surface of the channel layer 140 at the protruding portion, and is connected to the entire bottom surface and the side surface of the channel layer 140 at the protruding portion.

For example, the horizontal conductive layer 118 has a substrate shape that entirely covers the bottom surface and the side surface of the channel layer 140 at the protruding portion. For example, an entire outer surface of the horizontal conductive layer 118 is located on the same plane or may be a flat surface. A sum of a height of the protruding portion and a thickness of the horizontal conductive layer 118 on the protruding portion, and a thickness of the horizontal conductive layer 118 in a portion not provided with the protruding portion, is uniform as a whole. However, embodiments are not necessarily limited thereto. In other embodiments, an outer surface of the horizontal conductive layer 118 is curved according to a shape of the protruding portion, or the horizontal conductive layer 118 has various other shapes.

In the embodiment, electrical properties are increased by increasing a connection area between the channel layer 140 and the horizontal conductive layer 118. In addition, the channel layer 140 and the horizontal conductive layer 118 are connected by an easily performed process.

In an embodiment, the horizontal conductive layer 118 may also be referred to as a substrate, a common source electrode, a common source substrate, a common source line, etc. The horizontal conductive layer 118 includes a semiconductor layer doped with a p-type or n-type dopant. For example, the horizontal conductive layer 118 is doped with a dopant having the same conductivity type as that of a channel portion 140e. Current can stably flow through the horizontal conductive layer 118 doped with the dopant.

An example of a manufacturing method of a semiconductor device 30 shown in FIG. 9 is as follows.

A preliminary cell region is formed by forming the gate stacking structure 120, the channel structure CH, the first wiring portion 180, the second bonding structure 194, the insulating layer 196, etc., on a semiconductor substrate. For example, in an embodiment, the semiconductor substrate of the preliminary cell region is not formed on the circuit region 200a and is provided separately from the circuit region 200a. The horizontal conductive layer 118 shown in FIG. 9 is provided instead of the horizontal conductive layer 112 and 114 shown in FIG. 8. The structure of the preliminary cell region is the same as the cell region 100a shown in FIG. 8 except for the structure of the semiconductor substrate, the horizontal conductive layer 118 and the channel structure CH connected thereto.

In an embodiment, the semiconductor substrate includes a semiconductor material. For example, the semiconductor substrate includes or is made of a semiconductor material, or includes a semiconductor layer formed on a base substrate. For example, the semiconductor substrate includes or is made of at least one of a single crystal or polysilicon, epitaxial silicon, germanium, silicon-germanium, silicon-on-insulator, or germanium-on-insulator, etc.

After bonding the preliminary cell region to the circuit region 200a, the semiconductor substrate is removed. A process of removing the semiconductor substrate is at least one of an etching process, such as a wet etching process or a dry etching process, etc., a chemical mechanical polishing process, or a peeling process.

For example, the semiconductor substrate is removed by performing a chemical mechanical polishing process and a wet etching process using an etching material that can etch the semiconductor substrate. The etching material of the semiconductor substrate does not etch the cell insulating layer 132 or the gate dielectric layer 150, or has a low etch-rate for the cell insulating layer 132 and the gate dielectric layer 150, etc.

The gate dielectric layer 150 positioned on the protruding portion of the channel structure CH is removed. The process of removing the gate dielectric layer 150 is an etching process, such as a wet etching process, that uses an etching material that can etch the gate dielectric layer 150. Depending on embodiments, a compound portion 140f (see FIG. 2) is removed, or remains without being removed.

The horizontal conductive layer 118 is formed to cover the protruding portions of the plurality of channel structures CH and one surface of the gate stacking structure 120 exposed between the protruding portions of the plurality of channel structures CH. The horizontal conductive layer 118 can be formed using deposition, etc. In addition, the insulating layer 198b is further formed on an outer surface of the horizontal conductive layer 118.

An example of an electronic system that includes an above-described semiconductor device will be described in detail.

FIG. 10 schematically illustrates an electronic system that includes a semiconductor device according to an embodiment.

Referring to FIG. 10, an electronic system 1000 according to an embodiment includes the semiconductor device 1100 and a controller 1200 electrically connected to the semiconductor device 1100. The electronic system 1000 may be a storage device that includes one or a plurality of semiconductor devices 1100, or an electronic device that includes the storage device. For example, the electronic system 1000 is a solid state drive device (SSD) that includes one or a plurality of semiconductor devices 1100, a universal serial bus (USB), a computing system, a medical device, or a communication device.

In an embodiment, semiconductor device 1100 is a non-volatile memory device, and is, for example, a NAND flash memory device described with reference to FIGS. 1 to 5, 6A to 6F, 7A to 7D, 8 and 9. The semiconductor device 1100 includes the first structure 1100F and the second structure 1100S on the first structure 1100F. In an embodiment, the first structure 1100F is disposed next to the second structure 1100S. The first structure 1100F is a peripheral circuit structure that includes a decoder circuit 1110, a page buffer 1120 and a logic circuit 1130. The second structure 1100S is a memory cell structure that includes a bit line BL, a common source line CSL, a word line WL, first and second gate upper lines UL1 and UL2, first and second gate lower lines LL1 and LL2, and a memory cell string CSTR between the bit line BL and the common source line CSL.

In the second structure 1100S, each of the memory cell strings CSTR includes lower transistors LT1 and LT2 adjacent to the common source line CSL, upper transistors UT1 and UT2 adjacent to the bit line BL, and a plurality of memory cell transistors MCT disposed between the lower transistors LT1 and LT2 and the upper transistors UT1 and UT2. The number of lower transistors LT1 and LT2 and the number of upper transistors UT1 and UT2 may be variously modified according to embodiments.

In an embodiment, the lower transistors LT1 and LT2 include ground select transistors, and the upper transistors UT1 and UT2 include string select transistors. The first and second gate lower lines LL1 and LL2 are gate electrodes of the lower transistors LT1 and LT2, respectively. The word line WL is a gate electrode of the memory cell transistor MCT, and the gate upper lines UL1 and UL2 are gate electrodes of the upper transistors UT1 and UT2, respectively.

The common source line CSL, the first and second gate lower lines LL1 and LL2, the word line WL, and the first and second gate upper lines UL1 and UL2 are electrically connected to the decoder circuit 1110 through a first connection wire 1115 that extends from inside the first structure 1100F to the second structure 1100S. The bit line BL is electrically connected to the page buffer 1120 through a second connection wire 1125 that extends from inside the first structure 1100F to the second structure 1100S.

In the first structure 1100F, the decoder circuit 1110 and the page buffer 1120 execute a control operation on at least one of the plurality of memory cell transistors MCT.

The decoder circuit 1110 and the page buffer 1120 are controlled by the logic circuit 1130. The semiconductor device 1100 communicates with the controller 1200 through an input/output pad 1101 electrically connected to the logic circuit 1130. The input/output pad 1101 is electrically connected to the logic circuit 1130 through an input/output connection wire 1135 that extends from inside the first structure 1100F to the second structure 1100S.

The controller 1200 includes a processor 1210, a NAND controller 1220, and a host interface 1230. Depending on embodiments, the electronic system 1000 includes the plurality of semiconductor devices 1100, and, for example, the controller 1200 controls the plurality of semiconductor devices 1100.

The processor 1210 controls an overall operation of the electronic system 1000 and the controller 1200. The processor 1210 operates according to predetermined firmware, and accesses the semiconductor device 1100 by controlling the NAND controller 1220. The NAND controller 1220 includes a NAND interface 1221 that processes communication with the semiconductor device 1100. Through the NAND interface 1221, a control instruction that controls the semiconductor device 1100, data to be written to the memory cell transistor MCT of the semiconductor device 1100, and data to be read from the memory cell transistor MCT of the semiconductor device 1100, can be transmitted. The host interface 1230 provides a communication function between the electronic system 1000 and an external host. When a control instruction is received from an external host through the host interface 1230, the processor 1210 controls the semiconductor device 1100 in response to the control instruction.

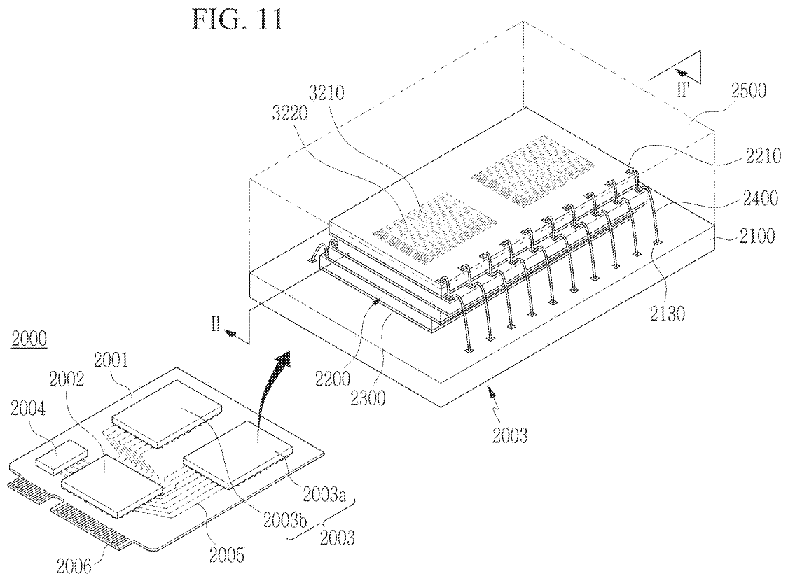

FIG. 11 is a schematic perspective view of an electronic system that includes a semiconductor device according to an embodiment.

Referring to FIG. 11, an electronic system 2000 according to an embodiment includes a main substrate 2001, a controller 2002 mounted on the main substrate 2001, one or more semiconductor packages 2003, and a DRAM 2004. The semiconductor package 2003 and the DRAM 2004 are connected to the controller 2002 through a wire pattern 2005 formed on the main substrate 2001.

The main substrate 2001 includes a connector 2006 that includes a plurality of pins that can couple to an external host. The number and disposition of the plurality of pins in the connector 2006 varies depending on the communication interface between the electronic system 2000 and the external host. In an embodiment, the electronic system 2000 communicates with an external host according to an interface such as one of a universal serial bus (USB), a peripheral component interconnect express (PCI-Express), a serial advanced technology attachment (SATA), or an M-Phy for universal flash storage (UFS), etc. In an embodiment, the electronic system 2000 operates with power supplied from an external host through the connector 2006. The electronic system 2000 further includes a power management integrated circuit (PMIC) that distributes the power received from the external host to the controller 2002 and the semiconductor package 2003.

The controller 2002 can write data to the semiconductor package 2003 or read data from the semiconductor package 2003, and can increase the operation speed of the electronic system 2000.

The DRAM 2004 is a buffer memory that mitigates a speed difference between the semiconductor package 2003, which is a data storage space, and an external host.

The DRAM 2004 in the electronic system 2000 can also operate as a cache memory, and provide a space for temporarily storing data in a control operation of the semiconductor package 2003. When the DRAM 2004 is included in the electronic system 2000, the controller 2002 further includes a DRAM controller that controls the DRAM 2004 in addition to the NAND controller that controls the semiconductor package 2003.

The semiconductor package 2003 includes first and second semiconductor packages 2003a and 2003b spaced apart from each other. The first and second semiconductor packages 2003a and 2003b each include a plurality of semiconductor chips 2200. Each of the first and second semiconductor packages 2003a and 2003b include a package substrate 2100, the semiconductor chip 2200 disposed on the package substrate 2100, an adhesive layer 2300 disposed on a lower surface of each semiconductor chip 2200, a connection structure 2400 that electrically connects the semiconductor chip 2200 and the package substrate 2100, and a molding layer 2500 that covers the semiconductor chip 2200 and the connection structure 2400 on the package substrate 2100.

The package substrate 2100 is a printed circuit board that includes a package upper pad 2130. Each semiconductor chip 2200 includes an input/output pad 2210. The input/output pad 2210 corresponds to the input/output pad 1101 of FIG. 10. Each semiconductor chip 2200 includes a gate stacking structure 3210 and a channel structure 3220. The semiconductor chip 2200 includes a semiconductor device described with reference to FIGS. 1 to 5, 6A to 6F, 7A to 7D, 8 and 9.

In an embodiment, the connection structure 2400 is a bonding wire that electrically connects the input/output pad 2210 and the package upper pad 2130. Accordingly, in each of the first and second semiconductor packages 2003a and 2003b, the semiconductor chips 2200 are electrically connected to each other using a bonding wire method, and are electrically connected to the upper package pad 2130 of the package substrate 2100. In some embodiments, in each of the first and second semiconductor packages 2003a and 2003b, the semiconductor chips 2200 are electrically connected to each other by a connecting structure that includes a through silicon via (TSV) instead of the connection structure 2400 that uses the bonding wire method.

In an embodiment, the controller 2002 and the semiconductor chip 2200 are included in one package. For example, the controller 2002 and the semiconductor chip 2200 are mounted on a separate interposer substrate that differs from the main substrate 2001, and the controller 2002 and the semiconductor chip 2200 are connected to each other by a wire formed on the interposer substrate.

FIGS. 12 and 13 are cross-sectional views that schematically illustrate semiconductor packages, respectively, according to embodiments. FIGS. 12 and 13 illustrate an embodiment of the semiconductor package 2003 of FIG. 11, and conceptually show a cross section taken along II-II′ line of the semiconductor package 2003 of FIG. 11.

Referring to FIG. 12, in an embodiment, in the semiconductor package 2003, the package substrate 2100 is a printed circuit board. The package substrate 2100 includes a package substrate body 2120, a package upper pad 2130 disposed on a top surface of the package substrate body 2120, a lower pad 2125 disposed on or exposed through a bottom surface of the package substrate body 2120, and an internal wire 2135 that electrically connects the upper pad 2130 and the lower pad 2125 inside the package substrate body 2120. The upper pad 2130 is electrically connected to the connection structure 2400. The lower pad 2125 is connected to the wire pattern 2005 of the main substrate 2010 of the electronic system 2000 through a conductive connection portion 2800, as shown in FIG. 11.

The semiconductor chip 2200 includes a semiconductor substrate 3010, and a first structure 3100 and a second structure 3200 sequentially stacked on the semiconductor substrate 3010. The first structure 3100 includes a peripheral circuit region that includes a peripheral wire 3110. The second structure 3200 includes a common source line 3205, a gate stacking structure 3210 disposed on the common source line 3205, a channel structure 3220 and a separation structure 3230 that penetrates the gate stacking structure 3210, a bit line 3240 electrically connected to the structure 3220, and a gate connection wire electrically connected to the word line WL (see FIG. 10) of the gate stacking structure 3210.

In the semiconductor chip 2200 or the semiconductor device according to an embodiment, a plurality of channel layers have the same crystal orientation, thereby increasing performance and productivity of the semiconductor chip 2200 or the semiconductor device.

Each of the semiconductor chips 2200 includes a through wire 3245 that is electrically connected to the peripheral wire 3110 of the first structure 3100 and extends into the second structure 3200. The through wire 3245 penetrates the gate stacking structure 3210, and is further disposed outside the gate stacking structure 3210. Each of the semiconductor chips 2200 further includes an input/output connection wire 3265 that is electrically connected to the peripheral wire 3110 of the first structure 3100 and extends into the second structure 3200, and the input/output pad 2210 that is electrically connected to the input/output connection wire 3265.

In an embodiment, the plurality of semiconductor chips 2200 in the semiconductor package 2003 are electrically connected to each other by the connection structure 2400 in the form of a bonding wire. For example, the plurality of semiconductor chips 2200 or the plurality of portions included in the plurality of semiconductor chips 2200 are electrically connected by a connection structure that includes a through electrode.

Referring to FIG. 13, in a semiconductor package 2003A according to an embodiment, each of the semiconductor chips 2200a includes a semiconductor substrate 4010, a first structure 4100 disposed on the semiconductor substrate 4010, and a second structure 4200 bonded to the first structure 4100 by a wafer bonding method.

The first structure 4100 includes a peripheral circuit region that includes a peripheral wire 4110 and a first bonding structure 4150. The second structure 4200 includes a common source line 4205, a gate stacking structure 4210 between the common source line 4205 and the first structure 4100, a channel structure 4220 and a separation structure 4230 that penetrates the gate stacking structure 4210, and a second bonding structure 4250 electrically connected to the word line WL (see FIG. 10) of the channel structure 4220 and the gate stacking structure 4210, respectively. For example, the second bonding structure 4250 is electrically connected to the channel structure 4220 and the word line WL via a bit line 4240 electrically connected to the channel structure 4220 and a gate connection wire electrically connected to the word line WL. The first bonding structure 4150 of the first structure 4100 and the second bonding structure 4250 of the second structure 4200 are bonded while in contact with each other. The bonded portion of the first bonding structure 4150 and the second bonding structure 4250 is made of, for example, copper (Cu).

In the semiconductor chip 2200a or the semiconductor device according to an embodiment, a plurality of channel layers have the same crystal orientation, thereby increasing performance and productivity of the semiconductor chip 2200a or the semiconductor device.

Each of the semiconductor chips 2200a further includes the input/output pad 2210 and an input/output connection wire 4265 under the input/output pad 2210. The input/output connection wire 4265 is electrically connected to a part of the second bonding structure 4250.

In an embodiment, the plurality of semiconductor chips 2200a in the semiconductor package 2003A are electrically connected to each other by the connection structure 2400 in the form of a bonding wire. For another example, the plurality of semiconductor chips 2200 or the plurality of portions in the plurality of semiconductor chips 2200 are electrically connected by a connection structure that includes a through electrode.

While embodiments of this disclosure have been described in detail, it is to be understood that the disclosure is not limited to disclosed embodiments. This disclosure is intended to cover various modifications and equivalent arrangements included within the spirit and scope of the appended claims.

What is claimed is:

1. A semiconductor device, comprising:
a gate stacking structure that includes a plurality of gate electrodes and a plurality of insulating layers alternately stacked with each other; and
a plurality of channel structures that penetrate the gate stacking structure,
wherein the plurality of channel structures include a first channel structure that includes a first channel layer, and a plurality of second channel structures adjacent the first channel structure and that include a plurality of second channel layers, and
the first channel layer in the first channel structure and the plurality of second channel layers in the plurality of second channel structures have a same crystal orientation.

2. The semiconductor device of claim 1, wherein crystal planes of the first channel layer and the plurality of second channel layers are one of (100) planes, (110) planes, or (111) planes, when viewed in a plan view.

3. The semiconductor device of claim 2, wherein the crystal planes of the first channel layer and the plurality of second channel layers are (100) planes, when viewed in a plan view.

4. The semiconductor device of claim 1, wherein the plurality of channel structures further includes a plurality of third channel structures that include a plurality of third channel layers,
a crystal orientation of the plurality of third channel layers and the crystal orientation of the first channel layer and the second channel layer are the same, and
a ratio of a number of main channel structures that include the first channel structure, the plurality of second channel structures, and the plurality of third channel structures to a total number of the plurality of channel structures exceeds 50%.

5. The semiconductor device of claim 4, wherein the ratio of the number of the main channel structures to the total number of the plurality of channel structures is 80% or more.

6. The semiconductor device of claim 5, wherein the ratio of the number of the main channel structures to the total number of the plurality of channel structures is 90% or more.

7. The semiconductor device of claim 1, wherein the first channel structure or at least one of the second channel structures includes a plurality of channel portions in a vertical direction, and
the plurality of channel portions of the first channel structure or the at least one of the second channel structures have the same crystal orientation.

8. The semiconductor device of claim 1, wherein the first channel structure or at least one of the second channel structures includes a semiconductor material, and
the first channel structure or at least one of the second channel structures includes a compound portion that includes a metal-semiconductor compound in which a metal and the semiconductor material are chemically bonded at a portion of the first channel structure or a portion of at least one of the second channel structures.

9. The semiconductor device of claim 8, wherein the compound portion includes a metal silicide.

10. An electronic system, comprising:
a main substrate;
a semiconductor device disposed on the main substrate; and
a controller electrically connected to the semiconductor device,
wherein the semiconductor comprises:
a gate stacking structure that includes a plurality of gate electrodes and a plurality of insulating layers alternately stacked with each other; and
a plurality of channel structures that penetrate the gate stacking structure,
wherein the plurality of channel structures include a first channel structure that includes a first channel layer, and a plurality of second channel structures adjacent to the first channel structure and that include a plurality of second channel layers, and
the first channel layer in the first channel structure and the plurality of second channel layers in the plurality of second channel structures have a same crystal orientation.

11. A manufacturing method of a semiconductor device, comprising:
forming a stacking structure that includes a plurality of sacrificial insulating layers and a plurality of insulating layers alternately stacked with each other;
forming a plurality of preliminary channel structures that penetrate the stacking structure and that include a plurality of preliminary channel layers, wherein each of the plurality of preliminary channel layers has an amorphous structure;
forming a plurality of channel layers that have a single crystal structure or a quasi-single crystal structure and have the same crystal orientation, by performing a heat treatment process that crystallizes the plurality of preliminary channel layers of the plurality of preliminary channel structures; and
forming a plurality of gate electrodes by replacing the plurality of sacrificial insulating layers with the plurality of gate electrodes.

12. The manufacturing method of claim 11, wherein the plurality of preliminary channel structures include a first preliminary channel structure that includes a first preliminary channel layer, and a plurality of second preliminary channel structures adjacent to the first preliminary channel structure and that include a plurality of second preliminary channel layers, and
wherein forming the plurality of channel layers includes respectively crystallizing the first preliminary channel layer and the plurality of second preliminary channel layers into a first channel layer and a plurality of second channel layers that have a same crystal orientation.

13. The manufacturing method of claim 11, further comprising:
positioning a metal-containing layer that includes a metal and has a single crystal structure or a quasi-single crystal structure on the plurality of preliminary channel structures, between forming the plurality of preliminary channel structures and forming the plurality of channel layers, and
removing the metal-containing layer from the stacking structure between forming of the plurality of channel layers and forming of the plurality of gate electrodes,
wherein, forming the plurality of channel layers includes crystallizing the plurality of preliminary channel layers by a metal-induced crystallization or a metal-induced lateral crystallization

14. The manufacturing method of claim 13, wherein, positioning the metal-containing layer includes positioning a metal-containing substrate that includes the metal-containing layer on the plurality of preliminary channel structures,
wherein the metal-containing substrate includes a semiconductor substrate, and the metal-containing layer is disposed on one side of the semiconductor substrate.

15. The manufacturing method of claim 13, wherein the metal-containing layer includes a metal-semiconductor compound in which a metal and a semiconductor material are chemically bonded.

16. The manufacturing method of claim 15, wherein the metal-containing layer includes a metal silicide.

17. The manufacturing method of claim 13, wherein the metal-containing layer has a thickness of 10 nm to 100 nm.

18. The manufacturing method of claim 13, further comprising forming an amorphous semiconductor layer on the stacking structure between forming the plurality of preliminary channel structures and positioning of the metal-containing layer,
wherein positioning the metal-containing layer includes positioning the metal-containing layer on the amorphous semiconductor layer.

19. The manufacturing method of claim 18, wherein the amorphous semiconductor layer has a thickness of 20 nm to 100 nm.

20. The manufacturing method of claim 13, wherein removing the metal-containing layer is performed by at least one of chemical mechanical polishing, dry etching, or wet etching.
